(19) United States
(12) Patent Application Publication
(10) Pub. No.: US 2026/0092208 A1
(43) Pub. Date: Apr. 2, 2026

(54) POLISHING COMPOSITION AND POLISHING METHOD

(71) Applicant: FUJIMI INCORPORATED, Kiyosu-shi (JP)

(72) Inventors: Shota Suzuki, Kiyosu-shi (JP); Tatsuhiko Hirano, Kiyosu-shi (JP); Kazuaki Iwasaki, Kiyosu-shi (JP); Shogo Tsubota, Kiyosu-shi (JP); Masaaki Ito, Kiyosu-shi (JP); Keiji Ashitaka, Kiyosu-shi (JP)

(73) Assignee: FUJIMI INCORPORATED, Kiyosu-shi (JP)

(21) Appl. No.: 19/341,297

(22) Filed: Sep. 26, 2025

(30) Foreign Application Priority Data
Sep. 30, 2024 (JP) 2024-170590

(51) Int. Cl. C09K 3/14; H01L 21/3105

(52) U.S. Cl. CPC C09K 3/1463; C09K 3/1436; H10P 95/06

(57) ABSTRACT

The present disclosure provides means that can achieve a high polishing removal rate of a material having a silicon-silicon bond and can satisfy a ratio of a polishing removal rate of the material having a silicon-silicon bond to a polishing removal rate of a material having an oxygen-silicon bond within a good range, when the pH of a polishing composition is less than 7. The present disclosure relates to a polishing composition containing the following component (A) and the following component (B) and having a pH of less than 7; component (A): surface-modified silica particles containing silica particles and a surface-modifying group that modifies a surface of the silica particles and contains a polyoxyalkylene chain having a weight average molecular weight of 80 or more and 7,000 or less; and component (B): water.

### CROSS-REFERENCE TO RELATED APPLICATION

The present application is based on Japanese Patent Laid-Open No. 2024-170590 A, filed on Sep. 30, 2024, the disclosure of which is hereby incorporated by reference in its entirety.

### TECHNICAL FIELD

The present disclosure relates to a polishing composition and a polishing method.

### BACKGROUND ART

In recent years, due to the multi-layer wiring of the surface of a semiconductor substrate, the so-called chemical mechanical polishing (CMP) technique is used to physically polish and planarize a semiconductor substrate when a device is manufactured. The CMP is a method of planarizing the surface of an object to be polished, such as a semiconductor substrate, using, for example, a polishing composition (slurry) containing abrasive grains (e.g., silica and/or ceria) and an additive (e.g., an anticorrosive agent and/or a surfactant). Specifically, the CMP is used in steps such as shallow trench isolation (STI), planarization of interlayer insulating films (ILD films), formation of tungsten plugs, and/or formation of multi-layer wiring formed of copper and low-dielectric constant films.

Japanese Patent Laid-Open No. 2009-256184 A discloses colloidal silica that is surface-modified by polyethylene oxide having a molecular weight of 15,000 or less, and a CMP polishing composition containing the same.

### SUMMARY

There is a demand for means that can improve a polishing removal rate of a material containing a silicon-silicon bond when the pH of a polishing composition is less than 7. However, the technique described in Japanese Patent Laid-Open No. 2009-256184 A is assumed to be used mainly for polishing wiring layers formed of a wiring material that is a copper-based material, barrier metal layers formed of a tantalum-based material, and/or insulating layers formed of a silica (silicon oxide)-based material. In addition, the technique in Japanese Patent Laid-Open No. 2009-256184 A assumes that the pH of the CMP polishing composition is 8 to 12. Moreover, Japanese Patent Laid-Open No. 2009-256184 A discloses that, with regard to the pH of the CMP polishing composition, when the pH of the CMP polishing composition is 6 or more and less than 8, there are cases where a sufficient polishing removal rate is not obtained, and when the pH of the CMP polishing composition is less than 6, the barrier layer is polished. However, Japanese Patent Laid-Open No. 2009-256184 A does not specifically disclose any effect of polishing the material containing a silicon-silicon bond. The technique of Japanese Patent Laid-Open No. 2009-256184 A has such a problem that when the pH of the polishing composition is less than 7, there are cases where the polishing removal rate of the material including a silicon-silicon bond is insufficient.

An object of the present disclosure is to provide means that can achieve a high polishing removal rate of a material having a silicon-silicon bond and satisfy a ratio of a polishing removal rate of the material having a silicon-silicon bond to a polishing removal rate of a material having an oxygen-silicon bond within a good range, when the pH of a polishing composition is less than 7.

In order to solve the above problems, the present inventors have conducted extensive research. As a result, they have found that at least one of the above problems can be solved by adding specific surface-modified silica particles to a polishing composition having a pH of less than 7, and have completed the present disclosure.

One aspect of the present disclosure to solve at least one of the above problems relates to a polishing composition containing the following component (A) and the following component (B) and having a pH of less than 7.
Component (A): surface-modified silica particles containing silica particles and a surface-modifying group that modifies a surface of the silica particles and contains a polyoxyalkylene chain having a weight average molecular weight of 80 or more and 7,000 or less; and
Component (B): water.

### DESCRIPTION OF EMBODIMENTS

### <Polishing Composition>

One aspect of the present disclosure relates to a polishing composition containing the following component (A) and the following component (B) and having a pH of less than 7.
Component (A): surface-modified silica particles containing silica particles and a surface-modifying group that modifies a surface of the silica particles and contains a polyoxyalkylene chain having a weight average molecular weight of 80 or more and 7,000 or less; and
Component (B): water.

In accordance with the polishing composition according to one embodiment of the present disclosure including such a configuration, it is possible to achieve a high polishing removal rate of a material having a silicon-silicon bond and satisfy a ratio of a polishing removal rate of the material having a silicon-silicon bond to a polishing removal rate of a material having an oxygen-silicon bond within a good range, when the pH of a polishing composition is less than 7.

The embodiments of the present disclosure are described below, but the present disclosure is not limited to the following embodiments. The embodiments described in the present specification can be optionally combined to form other embodiments.

In the present specification, “X to Y” indicating a numerical range is used to mean that the numerical values described before and after “to” (X and Y) are included as the lower limit and the upper limit, respectively, and means “X or more and Y or less”. In the present specification, “A and/or B” means that it includes each of the A and the B, and a combination thereof. In the present specification, unless otherwise specified, operations and measurements of physical properties and the like are performed under conditions of room temperature (20° C. or more and 25° C. or less) and relative humidity of 40% RH or more and 50% RH or less.

### [Component (A)]

The component (A) is surface-modified silica particles containing silica particles and a surface-modifying group that modifies a surface of the silica particles and contains a polyoxyalkylene chain having a weight average molecular weight of 80 or more and 7,000 or less.

In one embodiment, the component (A) is suitably used as polishing abrasive grains. It is preferable that the polishing composition according to one embodiment contains abrasive grains, and the abrasive grains contain the component (A). It is more preferable that the polishing composition according to one embodiment contains abrasive grains, and the abrasive grains consist of only the component (A).

In the present specification, surface-modified silica particles containing silica particles and a surface-modifying group that modifies a surface of the silica particles and contains a polyoxyalkylene chain having a weight average molecular weight of 80 or more and 7,000 or less are also referred to as “surface-modified silica particles of the component (A)”.

### (Silica Particles)

Examples of the silica particles contained in the surface-modified silica particles of the component (A) (simply also referred to as “silica particles” in the present specification) include fumed silica and colloidal silica, but are not particularly limited. The silica particles are preferably colloidal silica. Examples of the method for producing the colloidal silica include the sodium silicate method and the sol-gel method. However, colloidal silica produced by any of the above methods is suitably used. Among them, colloidal silica produced by the sol-gel method is preferable from the viewpoint of reducing metal impurities. The colloidal silica produced by the sol-gel method tends to have a low content of corrosive ions (e.g., metal impurities and/or chloride ions) that are diffusible in semiconductors. Production of the colloidal silica by the sol-gel method can be performed using a conventionally known method. As a specific example, colloidal silica can be obtained through the hydrolysis and condensation reaction using a silicon compound that can be hydrolyzed (e.g., alkoxysilane or derivatives thereof) as a raw material.

The lower limit of the average primary particle size of the silica particles, which is not particularly limited, is preferably 1 nm or more, more preferably 5 nm or more, and still more preferably 7 nm or more. As the average primary particle size of the abrasive grains increases, the polishing removal rate of the object to be polished by the polishing composition is improved. The upper limit of the average primary particle size of the silica particles, which is not particularly limited, is preferably 100 nm or less, more preferably 75 nm or less, and still more preferably 50 nm or less. The average primary particle size of the silica particles is calculated based on, for example, a specific surface area of the silica particles measured by the BET method.

The lower limit of the average secondary particle size of the silica particles, which is not particularly limited, is preferably 2 nm or more, more preferably 10 nm or more, still more preferably 15 nm or more, and particularly preferably 25 nm or more. Within such ranges, the resistance during polishing decreases, and stable polishing can be achieved. The upper limit of the average secondary particle size of the silica particles, which is not particularly limited, is preferably 200 nm or less, more preferably 150 nm or less, still more preferably 120 nm or less, and particularly preferably 90 nm or less. Within such ranges, the surface area per unit mass of the abrasive grains increases, the frequency of contact with the object to be polished increases, and the polishing removal rate is further improved. Examples of the range of the average secondary particle size of the silica particles include 2 nm or more and 200 nm or less, 10 nm or more and 150 nm or less, 15 nm or more and 120 nm or less, and 25 nm or more and 90 nm or less. The average secondary particle size of the silica particles can be measured by the dynamic light scattering method represented by the laser diffraction scattering method.

The average degree of association of the silica particles, which is not particularly limited, is preferably 5.0 or less, more preferably 4.0 or less, and still more preferably 3.0 or less. The average degree of association of the silica particles, which is not particularly limited, is preferably 1.0 or more, more preferably 1.2 or more, and still more preferably 1.5 or more. The average degree of association of the silica particles can be obtained by dividing a value of the average secondary particle size of the silica particles by a value of the average primary particle size of the silica particles.

The shape of the silica particles is not particularly limited, and may have a spherical shape or a non-spherical shape. Examples of the non-spherical shape include various shapes. Examples of the non-spherical shape include a polygonal prism shape, a cylindrical shape, a bale shape in which the center of a cylinder more bulges than the ends, a donut shape in which the center of a disk is penetrated, a plate shape, a so-called cocoon shape having a narrow part at the center, a so-called association-type sphere shape in which multiple particles are integrated, a so-called kompeito shape having a plurality of protrusions on the surface, and a rugby ball shape, but are not particularly limited. Examples of the polygonal prism shape include a triangular prism shape and a square prism shape, but are not particularly limited.

### (Surface-Modifying Group)

The surface-modified silica particles of the component (A) contains a surface-modifying group containing a polyoxyalkylene chain. The surface-modifying group contained in the surface-modified silica particles of the component (A) contains a polyoxyalkylene chain having a weight average molecular weight of 80 or more and 7,000 or less. In the present specification, the polyoxyalkylene chain contained in the surface-modifying group is also referred to as “polyoxyalkylene chain in the surface-modifying group”.

The polyoxyalkylene chain in the surface-modifying group may be composed of one kind of oxyalkylene or may be composed of two or more kinds of oxyalkylenes. Examples of the polyoxyalkylene chain in the surface-modifying group include a polyoxyethylene chain, a polyoxypropylene chain, a polyoxytrimethylene chain, a polyoxytetramethylene chain, a polyoxyisobutylene chain, a polyoxyethylene-polyoxypropylene chain, a polyoxyethylene-polyoxytetramethylene chain, and a polyoxyethylene-polyoxypropylene-polyoxyethylene chain, but are not particularly limited. When the polyoxyalkylene chain in the surface-modifying group is composed of two or more kinds of oxyalkylens, the binding form of two or more kinds of oxyalkylenes may be random, alternating, block, periodic, or any combination thereof. The polyoxyalkylene chain in the surface-modifying group preferably contains at least one kind of polyoxyalkylene chain selected from the group consisting of the polyoxyalkylene chains exemplified above. The polyoxyalkylene chain in the surface-modifying group is preferably at least one kind selected from the group consisting of a polyoxyethylene chain, a polyoxypropylene chain, a polyoxyethylene-polyoxypropylene chain, and a polyoxyethylene-polyoxypropylene-polyoxyethylene chain, and more preferably a polyoxyethylene chain.

The polyoxyalkylene chain in the surface-modifying group may have a structure in which an end of the polyoxyalkylene chain is capped. For example, the polyoxyalkylene chain in the surface-modifying group may have a structure in which an end of the polyoxyalkylene chain is capped with an aliphatic hydrocarbon group. The hydrogen atom in the hydroxy group at one end of the polyoxyalkylene chain in the surface-modifying group may be substituted with an aliphatic hydrocarbon group. Examples of the aliphatic hydrocarbon group that caps the end of the polyoxyalkylene chain in the surface-modifying group include an aliphatic hydrocarbon group having 1 or more and 10 or less carbon atoms, but are not particularly limited. Examples of the aliphatic hydrocarbon group having 1 or more and 10 or less carbon atoms include a straight-chain or branched alkyl group, a straight-chain or branched alkenyl group, and an alkynyl group, but are not particularly limited. Examples of the straight-chain or branched alkyl group include a methyl group, an ethyl group, a n-propyl group, an isopropyl group, a n-butyl group, an isobutyl group, a sec-butyl group, a tert-butyl group, a pentyl group, a hexyl group, a heptyl group, an octyl group, a 2-ethylhexyl group, and a decyl group, but are not particularly limited. Examples of the straight-chain or branched alkenyl group include a vinyl group and an allyl group, but are not particularly limited. Examples of the alkynyl group include an ethynyl group and a propynyl group, but are not particularly limited.

The weight average molecular weight (Mw) of the polyoxyalkylene chain contained in the surface-modifying group is 80 or more and 7,000 or less. That is, the weight average molecular weight (Mw) of the polyoxyalkylene chain in the surface-modifying group is 80 or more and 7,000 or less as the weight average molecular weight (Mw) of a compound containing a polyoxyalkylene chain. For example, the weight average molecular weight (Mw) of the polyoxyalkylene chain in the surface-modifying group is 80 or more and 7,000 or less as the weight average molecular weight (Mw) of the compound containing a polyoxyalkylene chain that is a raw material for constituting the polyoxyalkylene chain in the surface-modifying group. When the weight average molecular weight of the polyoxyalkylene chain in the surface-modifying group is less than 80, a ratio of a polishing removal rate of a material having a silicon-silicon bond to a polishing removal rate of a material having an oxygen-silicon bond decreases. When the weight average molecular weight of the polyoxyalkylene chain in the surface-modifying group is more than 7,000, there are cases where aggregation of the surface-modified silica particles occurs in the polishing composition having a pH of less than 7.

The lower limit of the weight average molecular weight of the polyoxyalkylene chain in the surface-modifying group is not particularly limited as long as it is 80 or more, but is preferably 100 or more, more preferably 140 or more, still more preferably 200 or more, and particularly preferably 300 or more. The upper limit of the weight average molecular weight of the polyoxyalkylene chain in the surface-modifying group is not particularly limited as long as it is 7,000 or less, but is preferably 5,000 or less, more preferably 2,000 or less, still more preferably 600 or less, and particularly preferably 500 or less. In one embodiment, examples of the weight average molecular weight of the polyoxyalkylene chain in the surface-modifying group include 80 or more and 5,000 or less, 80 or more and 2,000 or less, 80 or more and 600 or less, 80 or more and 500 or less, 100 or more and 5,000 or less, 140 or more and 2,000 or less, 200 or more and 600 or less, and 300 or more and 500 or less, but are not particularly limited. Within such ranges, a polishing removal rate of a material having a silicon-silicon bond is further improved, and a ratio of a polishing removal rate of the material having a silicon-silicon bond to a polishing removal rate of a material having an oxygen-silicon bond is satisfied within a better range, when the pH of a polishing composition is less than 7. The weight average molecular weight of the compound containing a polyoxyalkylene chain can be measured by gel permeation chromatography (GPC) using polyethylene glycol as a standard substance.

The surface-modifying group contained in the surface-modified silica particles of the component (A) preferably contains a silicon atom and a linkage group. Examples of the linkage group are described in the explanation of the formulas (1) to (3) that will be described later. The surface-modifying group contained in the surface-modified silica particles of the component (A) is more preferably at least one group selected from the group consisting of a group represented by the following formula (1), a group represented by the following formula (2), and a group represented by the following formula (3). The bonds marked with wavy lines in the following formulas (1) to (3) are bound to the surface of the silica particle.

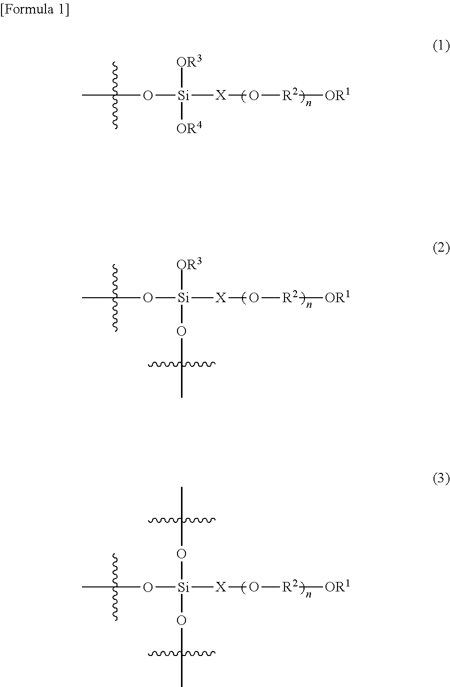

In the above formulas (1) to (3),
R¹ each independently represents a hydrogen atom or a hydrocarbon group having 1 or more and 30 or less carbon atoms,
R² each independently represents an alkylene group,
n is each independently an average degree of polymerization (number average degree of polymerization) of an oxyalkylene chain [—(O—R²)—] that represents the number of 2 or more and 200 or less,
X each independently represents a single bond or a linkage group (bivalent group having one or more atoms),
R³ and R⁴ each independently represent a hydrogen atom, an aliphatic hydrocarbon group having 1 or more and 3 or less carbon atoms, or a group represented by the following formula (a),

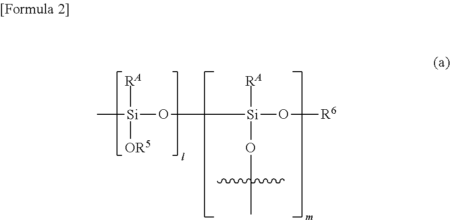

In the above formula (a), R^{A} each independently represents [—X—(O—R²)ₙ—OR¹], where X, R¹, R², and n in R^{A} are the same as X, R¹, R², and n defined in the above formulas (1) to (3), respectively, R⁵ and R⁶ each independently represent a hydrogen atom or an aliphatic hydrocarbon group having 1 or more and 3 or less carbon atoms, and 1 and m each independently represent the number of 0 or more. Note that, in the formula (a), the bond extending to the left from the silicon atom is bonded to the oxygen atom. The bond marked with the wavy line in the formula (a) is bound to the surface of the silica particle.

In the above formulas (1) to (3), examples of the hydrocarbon group having 1 or more and 30 or less carbon atoms used in R¹ include an alkyl group, an alkenyl group, a phenyl group, a naphthyl group, an alkyl aryl group, an arylalkyl group, and an aryl alkenyl group, but are not particularly limited. Examples of the alkyl group include a methyl group, an ethyl group, a propyl group, an isopropyl group, a n-butyl group, a sec-butyl group, a tert-butyl group, an isobutyl group, an amyl group, an isoamyl group, a tert-amyl group, a n-hexyl group, a cyclohexyl group, a cyclohexylmethyl group, a 2-cyclohexylethyl group, a n-heptyl group, an isoheptyl group, a tert-heptyl group, a n-octyl group, an isooctyl group, a tert-octyl group, a 2-ethylhexyl group, a n-nonyl, an isononyl group, a n-decyl group, a n-undecyl group, a n-dodecyl group, a n-tridecyl group, a n-tetradecyl group, a n-pentadecyl group, a n-hexadecyl group, a n-heptadecyl group, and a n-octadecyl group, but are not particularly limited. Examples of the alkenyl group include a vinyl group, a 1-methylethenyl group, a 2-methylethenyl group, a propenyl group, a butenyl group, an isobutenyl group, a pentenyl group, a hexenyl group, a heptenyl group, an octenyl group, a decenyl group, a pentadecenyl group, and a 1-phenylpropen-3-yl, but are not particularly limited. Examples of the alkyl aryl group include a 2-methylphenyl group, a 3-methylphenyl group, a 4-methylphenyl group, a 4-vinylphenyl group, a 3-isopropyl phenyl group, a 4-isopropyl phenyl group, a 4-butyl phenyl group, a 4-isobutyl phenyl group, a 4-tert-butyl phenyl group, a 4-hexyl phenyl group, a 4-cyclohexyl phenyl group, a 4-octylphenyl group, a 4-(2-ethylhexyl)phenyl group, a 4-stearyl phenyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, and a 2,4-di-tert-butyl phenyl group, but are not particularly limited. Examples of the arylalkyl group include a benzyl group, a phenethyl group, a 2-phenylpropan-2-yl group, a diphenylmethyl group, and a triphenylmethyl group, but are not particularly limited. Examples of the aryl alkenyl group include a styryl group and a cinnamyl group, but are not particularly limited.

In the above formulas (1) to (3), R² represents an alkylene group, and is preferably an alkylene group having 1 or more and 4 or less carbon atoms. Examples of the alkylene group having 1 or more and 4 or less carbon atoms include a methylene group, an ethylene group, a propylene group (methylethylene group), a trimethylene group, a butylene group (tetramethylene group), and an isobutylene group, but are not particularly limited. Among them, R² is preferably an ethylene group or a propylene group. A plurality of R²s may be the same or different, respectively. When a plurality of R²s are different, the binding form of the oxyalkylene chain [—(O—R²)-] may be random, alternating, block, periodic, or any combination thereof.

In the above formulas (1) to (3), n is an average degree of polymerization (number average degree of polymerization) of an oxyalkylene chain [—(O—R²)-] that represents the number of 2 or more and 200 or less. n is preferably the number of 3 or more and 150 or less, more preferably the number of 4 or more and 100 or less, still more preferably the number of 5 or more and 50 or less, and particularly preferably the number of 6 or more and 10 or less. Within such ranges, a polishing removal rate of a material having a silicon-silicon bond is further improved and a ratio of a polishing removal rate of the material having a silicon-silicon bond to a polishing removal rate of a material having an oxygen-silicon bond is satisfied within a better range, when the pH of a polishing composition is less than 7.

In the above formulas (1) to (3), X represents a single bond or a linkage group (bivalent group having one or more atoms). Examples of the linkage group include a bivalent hydrocarbon group, a urethane bond, a carbonyl group, an ether bond, an ester bond, a carbonate group, an amide group, and a group in which one or more kinds thereof are linked in multiple number (a group in which at least one kind selected from the group consisting of these are linked in multiple number), but are not particularly limited.

Examples of the bivalent hydrocarbon group include a straight-chain alkylene group having 1 or more and 18 or less carbon atoms, a branched alkylene group having 1 or more and 18 or less carbon atoms (e.g., a branched alkylene group having 3 or more and 18 or less carbon atoms), or a cyclic alkylene group having 1 or more and 18 or less carbon atoms (e.g., a cyclic alkylene group having 3 or more and 18 or less carbon atoms), but are not particularly limited. Examples of the straight-chain alkylene group having 1 or more and 18 or less carbon atoms, the branched alkylene group having 1 or more and 18 or less carbon atoms (e.g., a branched alkylene group having 3 or more and 18 or less carbon atoms), or the cyclic alkylene group having 1 or more and 18 or less carbon atoms (e.g., a cyclic alkylene group having 3 or more and 18 or less carbon atoms) include a methylene group, a methyl methylene group, a dimethyl methylene group, an ethylene group, a propylene group (methylethylene group), a trimethylene group, a butylene group (tetramethylene group), a 1-methyl propylene group, a 2-methyl propylene group, a 1,2-dimethyl propylene group, a 1,3-dimethyl propylene group, a 1-methyl butylene group, a 2-methyl butylene group, a 3-methyl butylene group, a 2,4-dimethyl butylene group, a 1,3-dimethyl butylene group, a n-pentylene group, a n-hexylene group, a n-heptylene group, a n-octylene group, an ethane-1,1-diyl group, a propane-2,2-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, a heptadecane-1,17-diyl group, an octadecane-1,18-diyl group, a cyclopentane-1,2-diyl group, a cyclopentane-1,3-diyl group, a cyclohexane-1,1-diyl group, a cyclohexane-1,2-diyl group, a cyclohexane-1,3-diyl group, a cyclohexane-1,4-diyl group, a methylcyclohexane-1,4-diyl group, and a cyclohexane-1,4-dimethylene group, but are not particularly limited.

The linkage group, for example, the linkage group in the above X preferably contains a urethane bond, and is preferably a group that contains a bivalent hydrocarbon group (particularly, a straight-chain or branched alkylene group) and a urethane bond from the viewpoint of easy synthesis. The silicon atom in the above formulas (1) to (3) and the bivalent hydrocarbon group in X (particularly, a straight-chain or branched alkylene group) are preferably directly bound. Specifically, the above linkage group, for example, X is more preferably-(CH₂)ₖ—NH—C(═O)— (the C at the left end is bound to the silicon atom, and the C at the right end is bound to the O in the polyoxyalkylene chain). Note that, in the above formula, k represents the number of 1 or more and 18 or less, preferably the number of 1 or more and 6 or less, and more preferably the number of 1 or more and 3 or less.

In the above formula (1), R³ and R⁴ each independently represent a hydrogen atom, or an aliphatic hydrocarbon group having 1 or more and 3 or less carbon atoms. Examples of the aliphatic hydrocarbon group having 1 or more and 3 or less carbon atoms include an alkyl group, an alkenyl group, and an alkynyl group, but are not particularly limited. Examples of the alkyl group include a methyl group, an ethyl group, propyl group, and an isopropyl group, but are not particularly limited. Examples of the alkenyl group include a vinyl group and an allyl group, but are not particularly limited. Examples of the alkynyl group include an ethynyl group and a propynyl group, but are not particularly limited. Among them, R³ and R⁴ are, each independently, preferably an alkyl group, and both R³ and R⁴ are more preferably an alkyl group. Note that, R³ in the formula (2) is the same as R³ in the formula (1).

In the above formula (a), R^{A} represents [—X—(O—R²)ₙ—OR¹]. X, R¹, R², and n in R^{A} are the same as those exemplified and explained in the above formulas (1) to (3), respectively, and the preferable embodiments are the same. The binding form in the case where there are two or more kinds of oxyalkylene chains [—(O—R²)-] is also as described above. Note that, the bond extending to the left from the silicon atom is bonded to the oxygen atom. The bond marked with the wavy line in the formula is bound to the surface of the silica particle.

In the above formula (a), R⁵ and R⁶ each independently represent a hydrogen atom or an aliphatic hydrocarbon group having 1 or more and 3 or less carbon atoms. Examples of the aliphatic hydrocarbon group having 1 or more and 3 or less carbon atoms include a straight-chain or branched alkyl group, a straight-chain or branched alkenyl group, and an alkynyl group. Examples of the straight-chain or branched alkyl group include a methyl group, an ethyl group, a n-propyl group, and an isopropyl group, but are not particularly limited. Examples of the straight-chain or branched alkenyl group include a vinyl group, an allyl group, and a propenyl group, but are not particularly limited. Examples of the alkynyl group include an ethynyl group and a propynyl group, but are not particularly limited. Among them, R⁵ and R⁶ are each independently preferably a straight-chain or branched alkyl group, and both R⁵ and R⁶ are more preferably a straight-chain or branched alkyl group.

In the above formula (a), 1 and m each independently represent the number of 0 or more. The binding order of the constituent unit to which 1 is added and the constituent unit to which m is added is not particularly limited. That is, the silicon atom, in the formula (a), that is bonded to the oxygen atom in the formula (1) or (2) may be the silicon atom in the constituent unit to which 1 is added, or may be the silicon atom in the constituent unit to which m is added. Similarly, the oxygen atom, in the formula (a), that is bonded to R⁶ in the formula (a) may be the oxygen atom in the constituent unit to which 1 is added, or may be the oxygen atom in the constituent unit to which m is added. In addition, when one selected from the group consisting of l and m is the number of 1 or more and the other is the number of 2 or more, the binding form between the constituent unit to which 1 is added and the constituent unit to which m is added may be random, alternating, block, periodic, or any combination thereof.

When the surface-modified silica particles of the component (A) have a plurality of “R¹”s, a plurality of “R²”s, a plurality of “R³”s, a plurality of “R⁴”s, a plurality of “R⁵”s, a plurality of “R⁶”s, a plurality of “X”s, a plurality of “l”s, a plurality of “m”s, and/or a plurality of “n”s, a plurality of “R¹”s, a plurality of “R²”'s, a plurality of “R³”s, a plurality of “R⁴”s, a plurality of “R⁵”s, a plurality of “R⁶”s, a plurality of “X”s, a plurality of “I”s, and a plurality of “m”s, and a plurality of “n”s may be each independently the same or different.

In the above formulas (1) and (2), the structure in which R³ and/or R⁴ is a hydrogen atom represents, for example, a structure in which an unreacted alkoxysilyl group in the surface-modifying group bound to the silica particle is hydrolyzed. In the above formulas (1) and (2), the structure in which R³ and/or R⁴ is an aliphatic hydrocarbon group having 1 or more and 3 or less carbon atoms represents, for example, a structure in which an unreacted alkoxysilyl group in the surface-modifying group bound to the silica particle remains. In the above formulas (1) and (2), the structure in which R³ and/or R⁴ is a group represented by the above formula (a) represents, for example, a structure in which an unreacted alkoxysilyl group in the surface-modifying group bound to the silica particle reacts with an unreacted polyoxyalkylene chain-containing silane coupling agent that will be described later, a structure in which an unreacted alkoxysilyl group in the surface-modifying group bound to the silica particle reacts with an alkoxysilyl group in another surface-modifying group bound to the silica particle by dehydration condensation, or a structure in which an unreacted alkoxysilyl group in the surface-modifying group bound to the silica particle, an unreacted polyoxyalkylene chain-containing silane coupling agent that will be described later, and an alkoxysilyl group in another surface-modifying group bound to the silica particle by dehydration condensation are allowed to react with each other.

The component (A) preferably contains silica particles containing a compound containing a polyoxyalkylene chain fixed on a surface of the particles through a silane coupling agent.

In the silica particles containing a compound containing a polyoxyalkylene chain fixed on a surface of the particles through a silane coupling agent, the silane coupling agent is not particularly limited. Preferable examples of the silane coupling agent include an isocyanate group-containing silane coupling agent. In the silica particles containing a compound containing a polyoxyalkylene chain fixed on a surface of the particles through a silane coupling agent, the silane coupling agent is not particularly limited, but preferably contains an isocyanate group-containing silane coupling agent, and more preferably consists of only an isocyanate group-containing silane coupling agent. Examples of the isocyanate group-containing silane coupling agent include 3-isocyanate propyl trimethoxysilane, 3-isocyanate propyl dimethoxymethylsilane, 3-isocyanate propyl triethoxysilane, isocyanate methyltrimethoxysilane, isocyanate methyltriethoxysilane, and isocyanate methyldimethoxymethylsilane, but are not particularly limited. These silane coupling agents can be used singly or in combination of two or more thereof. The silane coupling agent preferably contains at least one kind of silane coupling agent selected from the group consisting of the silane coupling agents exemplified above. The silane coupling agent is preferably an isocyanate group-containing silane coupling agent, and is more preferably 3-isocyanate propyl trimethoxysilane. As the silane coupling agent, a commercially available product may be used or a synthesized product may be used.

In one embodiment, in the silica particles containing a compound containing a polyoxyalkylene chain fixed on a surface of the particles through a silane coupling agent, the compound containing a polyoxyalkylene chain is preferably a compound composed of only a polyalkylene glycol chain. The ends of the compound composed of only a polyalkylene glycol chain are not capped. For example, the compound composed of only a polyalkylene glycol chain may be the same as the compound composed of only a polyalkylene glycol chain exemplified in the description of the compound containing a polyoxyalkylene chain having a weight average molecular weight of 80 or more and 7,000 or less that will be described later. The compound composed of only a polyalkylene glycol chain is more preferably at least one compound selected from the group consisting of polyethylene glycol, polypropylene glycol, and a polyethylene glycol-polypropylene glycol copolymer, and is more preferably polyethylene glycol. The compound containing a polyoxyalkylene chain is preferably polyalkylene glycol.

The lower limit of the average secondary particle size of the surface-modified silica particles in the polishing composition according to one embodiment, which is not particularly limited, is preferably 2 nm or more, more preferably 10 nm or more, still more preferably 15 nm or more, and particularly preferably 25 nm or more. Within such ranges, the resistance during polishing decreases, and stable polishing can be achieved. The upper limit of the average secondary particle size of the surface-modified silica particles in the polishing composition according to one embodiment, which is not particularly limited, is preferably 200 nm or less, more preferably 150 nm or less, still more preferably 120 nm or less, and particularly preferably 90 nm or less. Within such ranges, the surface area per unit mass of the abrasive grains increases, the frequency of contact with the object to be polished increases, and the polishing removal rate is further improved. Examples of the range of the average secondary particle size of the surface-modified silica particles in the polishing composition according to one embodiment include 2 nm or more and 200 nm or less, 10 nm or more and 150 nm or less, 15 nm or more and 120 nm or less, and 25 nm or more and 90 nm or less. The average secondary particle size of the surface-modified silica particles in the polishing composition according to one embodiment can be measured by, for example, the dynamic light scattering method represented by the laser diffraction scattering method.

The content of the component (A) in the polishing composition according to one embodiment is not particularly limited. The lower limit of the content of the component (A) is preferably 0.1% by mass or more, more preferably 0.2% by mass or more, still more preferably 0.5% by mass or more, even still more preferably 1% by mass or more, and particularly preferably 1.5% by mass or more, relative to the total mass of the polishing composition. The lower limit of the content of the component (A) may be, for example, 2% by mass or more relative to the total mass of the polishing composition. The upper limit of the content of the surface-modified silica particles of the component (A) (the upper limit of the content of the component (A)) is preferably 20% by mass or less, more preferably 15% by mass or less, still more preferably 10% by mass or less, even still more preferably 8% by mass or less, and further still more preferably 6% by mass or less, and particularly preferably 5% by mass or less (the lower limit of more than 0% by mass), relative to the total mass of the polishing composition. Within such ranges, the polishing removal rate can be improved while cost is suppressed. Examples of the range of the content of the component (A) include 0.1% by mass or more and 20% by mass or less, 0.2% by mass or more and 15% by mass or less, 0.5% by mass or more and 10% by mass or less, 1% by mass or more and 8% by mass or less, 1.5% by mass or more and 6% by mass or less, and 2% by mass or more and 5% by mass or less, relative to the total mass of the polishing composition, but are not particularly limited. When the polishing composition according to one embodiment contains two or more kinds of surface-modified silica particles as the component (A), the content of the component (A) represents the total content thereof.

### (Method for Producing Surface-Modified Silica Particles)

The method for producing the surface-modified silica particles of the component (A) is not particularly limited, and a known method may be appropriately used. Examples of the method for producing the surface-modified silica particles of the component (A) include the following method (a1) and the following method (b1).
(a1) a method including: previously synthesizing a polyoxyalkylene chain-containing silane coupling agent (also referred to as “surface-modifying agent” in the present specification) using a silane coupling agent having a group that can react with an end hydroxy group of the compound containing a polyoxyalkylene chain having a weight average molecular weight of 80 or more and 7,000 or less, and a compound containing a polyoxyalkylene chain; and allowing the polyoxyalkylene chain-containing silane coupling agent and silica particles (preferably colloidal silica) to react.
(b1) a method including: allowing a silane coupling agent having a group that can react with an end hydroxy group of the compound containing a polyoxyalkylene chain having a weight average molecular weight of 80 or more and 7,000 or less, and silica particles (preferably colloidal silica) to react; and then allowing the compound containing a polyoxyalkylene chain having a weight average molecular weight of 80 or more and 7,000 or less to further react.

Among them, the method (a1) is preferably used because reaction is easily controlled and the production cost can be further decreased. The method (a1) will be described below.

### <<Step of Synthesizing Polyoxyalkylene Chain-Containing Silane Coupling Agent>>

In the present step, a silane coupling agent having a group that can react with an end hydroxy group of a compound containing a polyoxyalkylene chain and the compound containing a polyoxyalkylene chain having a weight average molecular weight of 80 or more and 7,000 or less are allowed to react to synthesize a polyoxyalkylene chain-containing silane coupling agent (surface-modifying agent).

The silane coupling agent having a group that can react with an end hydroxy group of the compound containing a polyoxyalkylene chain is not particularly limited, but is preferably an isocyanate group-containing silane coupling agent. Examples of the isocyanate group-containing silane coupling agent include 3-isocyanate propyl trimethoxysilane, 3-isocyanate propyl dimethoxymethylsilane, 3-isocyanate propyl triethoxysilane, isocyanate methyltrimethoxysilane, isocyanate methyltriethoxysilane, and isocyanate methyldimethoxymethylsilane, but are not particularly limited. These silane coupling agents can be used singly or in combination of two or more thereof. The silane coupling agent preferably contains at least one kind of silane coupling agent selected from the group consisting of the silane coupling agents exemplified above. The silane coupling agent is preferably an isocyanate group-containing silane coupling agent, and more preferably 3-isocyanate propyl trimethoxysilane. As the silane coupling agent, a commercially available product may be used or a synthesized product may be used.

Examples of the compound containing a polyoxyalkylene chain having a weight average molecular weight of 80 or more and 7,000 or less include polyethylene glycol, polypropylene glycol, polytrimethylene glycol, polytetramethylene glycol, polyisobutylene glycol, an ethylene glycol-propylene glycol copolymer, and an ethylene glycol-tetramethylene glycol copolymer, but are not particularly limited. Note that, the binding form of the copolymer may be random, alternating, block, periodic, or any combination thereof. These compounds containing a polyoxyalkylene chain can be used singly or in combination of two or more thereof. The compound containing a polyoxyalkylene chain preferably contains at least one kind of compound containing a polyoxyalkylene chain selected from the group consisting of the compounds containing a polyoxyalkylene chain exemplified above. The compound containing a polyoxyalkylene chain is preferably polyalkylene glycol, more preferably at least one compound selected from the group consisting of polyethylene glycol, polypropylene glycol, and a polyethylene glycol-polypropylene glycol copolymer, and still more preferably polyethylene glycol. The preferable embodiment of the weight average molecular weight of the compound containing a polyoxyalkylene chain is the same as the preferable embodiment of the weight average molecular weight of the above polyoxyalkylene chain.

For example, the compound containing a polyoxyalkylene chain having a weight average molecular weight of 80 or more and 7,000 or less may have a structure in which one end of the polyoxyalkylene chain is capped. For example, the compound containing a polyoxyalkylene chain having a weight average molecular weight of 80 or more and 7,000 or less may have a structure in which one end of the polyoxyalkylene chain is capped with an aliphatic hydrocarbon group. That is, a hydrogen atom in the hydroxy group of one end of the compound containing a polyoxyalkylene chain having a weight average molecular weight of 80 or more and 7,000 or less may be substituted with an aliphatic hydrocarbon group. Examples of the aliphatic hydrocarbon group that caps one end of the compound containing a polyoxyalkylene chain having a weight average molecular weight of 80 or more and 7,000 or less include an aliphatic hydrocarbon group having 1 or more and 10 or less carbon atoms, but are not particularly limited. Examples of the aliphatic hydrocarbon group having 1 or more and 10 or less carbon atoms include a straight-chain or branched alkyl group, a straight-chain or branched alkenyl group, and an alkynyl group, but are not particularly limited. Examples of the alkynyl group include an ethynyl group and a propynyl group, but are not particularly limited.

In one embodiment, the compound containing a polyoxyalkylene chain is preferably polyalkylene glycol, a compound having a structure in which one end of the polyoxyalkylene chain is capped, or a combination thereof.

As the compound containing a polyoxyalkylene chain, a commercially available product may be used or a synthesized product may be used.

The reaction between the above silane coupling agent and the compound containing a polyoxyalkylene chain is not particularly limited, and may be performed in, for example, an inorganic solvent or an organic solvent. Examples of the organic solvent that can be used include an aliphatic hydrocarbon, an aromatic hydrocarbon, an alicyclic hydrocarbon, an aprotic polar solvent, a halogenated hydrocarbon, a chain or cyclic ether, an ester, a chain ketone, and a nitrile, but are not particularly limited. Examples of the aliphatic hydrocarbon include hexane, heptane, and octane, but are not particularly limited. Examples of the aromatic hydrocarbon include benzene, toluene, and xylene, but are not particularly limited. Examples of the alicyclic hydrocarbon include cyclohexane and methylcyclohexane, but are not particularly limited. Examples of the aprotic polar solvent include dimethylformamide (DMF), dimethylacetamide, N-methylpyrrolidone, and dimethylsulfoxide, but are not particularly limited. Examples of the halogenated hydrocarbon include chloroform, dichloromethane, dichloroethane, carbon tetrachloride, chlorobenzene, and trifluoromethyl benzene, but are not particularly limited. Examples of the chain or cyclic ether include diethyl ether, diisopropyl ether, dimethoxyethane, tetrahydrofuran (THF), and dioxane, but are not particularly limited. Examples of the ester include ethyl acetate and butyl acetate, but are not particularly limited. Examples of the chain ketone include methyl ethyl ketone (MEK) and methyl isobutyl ketone, but are not particularly limited. Examples of the nitrile include acetonitrile, but are not particularly limited.

The silane coupling agent and the compound containing a polyoxyalkylene chain are mixed to obtain a surface-modifying agent. As the mixing method, a method of adding the silane coupling agent to the compound containing a polyoxyalkylene chain, followed by mixing is preferable. In this case, as the addition form of the silane coupling agent, it may be added all at once, may be added in portions, or may be added continuously. In the case of the continuous addition, the addition rate can be appropriately adjusted. When the compound containing a polyoxyalkylene chain is solid, the compound containing a polyoxyalkylene chain may be heated before mixing to make the compound containing a polyoxyalkylene chain liquid, followed by mixing.

The stirring rate during mixing is not particularly limited and may be appropriately set. The mixing time is preferably 15 minutes or more and 2 hours or less.

The reaction temperature after mixing is preferably 20° C. or more and 200° C. or less, and more preferably 50° C. or more and 150° C. or less. The reaction time after mixing is preferably the time when the intensity of the peak of the isocyanate group derived from the silane coupling agent at about 2,260 cm-1 is 10% or less compared to that immediately after mixing when the FT-IR spectrum of the surface-modifying agent is measured, and more preferably the time when the peak disappears. The reaction atmosphere may be, for example, an air atmosphere, a nitrogen atmosphere, an argon atmosphere, or other inert gas atmosphere, and is not particularly limited. The pressure during the reaction may be, for example, normal pressure (atmospheric pressure), pressurized pressure, or reduced pressure, and is not particularly limited. Since the reaction can proceed under normal pressure (atmospheric pressure), the reaction is preferably performed under normal pressure (atmospheric pressure).

The mixing molar ratio of the silane coupling agent to the compound containing a polyoxyalkylene chain (silane coupling agent/compound containing a polyoxyalkylene chain) is preferably 0.5 or more and 1.5 or less.

As described above, the surface-modifying agent can be obtained. The structure of the surface-modifying agent can be confirmed by, for example, measuring the infrared absorption spectrum by the total reflection method (ATR method) using a Fourier transformation infrared spectrophotometer (FT-IR). The details of this method are described in the Examples.

After this step is performed, the surface-modifying agent may be isolated and purified. The next step (step of allowing silica particles and surface-modifying agent to react) may be performed without isolation and purification.

### <<Step of Allowing Silica Particles and Surface-Modifying Agent to React>>

The surface-modifying agent obtained above and silica particles are preferably allowed to react, to obtain the surface-modified silica particles of the component (A). The above silica particles have a silanol group on the surfaces thereof. This silanol group becomes a reaction part, and forms a siloxane bond with the surface-modifying agent.

The surface-modifying agent (polyoxyalkylene chain-containing silane coupling agent) is preferably a compound represented by the following formula (1′). The surface-modifying agent may be used alone or in combination of two or more kinds thereof.

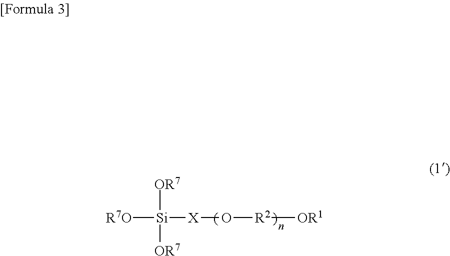

In the above formula (1′), each of R¹, R², X, and n is the same as those exemplified and explained in the above formulas (1) to (3), and the preferable aspects are also the same. When two or more compounds represented by the above formula (1′) are used, a plurality of R¹s, a plurality of R²s, a plurality of Xs, and a plurality of ns may be each independently the same or different.

In the above formula (1′), R⁷ each independently represents an aliphatic hydrocarbon group having 1 or more and 3 or less carbon atoms. Examples of the above aliphatic hydrocarbon group having 1 or more and 3 or less carbon atoms include a straight-chain or branched alkyl group, a straight-chain or branched alkenyl group, and an alkynyl group. Examples of the straight-chain or branched alkyl group include a methyl group, an ethyl group, a propyl group, and an isopropyl group, but are not particularly limited. Examples of the straight-chain or branched alkenyl group include a vinyl group, an allyl group, and a propenyl group, but are not particularly limited. Examples of the alkynyl group include an ethynyl group and a propynyl group, but are not particularly limited. Among them, R⁷ is each independently preferably a straight-chain or branched alkyl group, and all R⁷s are more preferably a straight-chain or branched alkyl group.

The step of allowing the surface-modifying agent and silica particles to react is preferably performed in a solvent. Examples of the solvent include water and an organic solvent, but are not particularly limited. The solvent may be used alone or in combination of two or more kinds thereof. Examples of the organic solvent include the substances exemplified in the explanation of the step of synthesizing the polyoxyalkylene chain-containing silane coupling agent, and an alcohol, but are not particularly limited. Examples of the alcohol include methanol and ethanol, but are not particularly limited.

The mixed solution, which contains the silica particles, the surface-modifying agent, and the solvent, is preferably allowed to react in a reaction vessel under stirring. A ratio between the silica particles to be subjected to the reaction and the surface-modifying agent to be subjected to the reaction is appropriately selected depending on the degree of desired surface modification. As one example of the ratio between the silica particles and the surface-modifying agent is exemplified, regarding the ratio between the silica particles and the surface-modifying agent, the amount of the surface-modifying agent used is preferably 0.1 parts by mass or more and 40 parts by mass or less, and more preferably 0.5 parts by mass or more and 30 parts by mass or less, relative to 100 parts by mass of the silica particles.

The method of mixing the silica particles and the surface-modifying agent is not particularly limited, but a method of adding the surface-modifying agent to the silica particles, followed by mixing is preferable. In this case, as the addition form of the silica particles, it may be added all at once, may be added in portions, or may be added continuously. The stirring rate during mixing is not particularly limited and can be appropriately set.

The reaction temperature is preferably 20° C. or more and 200° C. or less, and more preferably 30° C. or more and 150° C. or less. The reaction time is preferably 1 hour or more and 50 hours or less, and more preferably 2 hours or more and 30 hours or less. The reaction atmosphere may be, for example, an air atmosphere, a nitrogen atmosphere, an argon atmosphere, or other inert gas atmospheres, and is not particularly limited. The pressure during the reaction may be, for example, normal pressure (atmospheric pressure), pressurized pressure, or reduced pressure, and is not particularly limited. Since the reaction according to the present disclosure can proceed under normal pressure (atmospheric pressure), the reaction is preferably performed under normal pressure (atmospheric pressure).

The surface-modified silica particles of the component (A) are obtained through a step of synthesizing the polyoxyalkylene chain-containing silane coupling agent (surface-modifying agent) and a step of allowing the surface-modifying agent and silica particles to react.

When a dispersing liquid containing the surface-modified silica particles of the component (A) obtained contains a dispersing medium other than water, the dispersing medium other than water may be replaced with water if necessary. The method for replacing the dispersing medium other than water with water is not particularly limited, and examples thereof include a method in which a certain amount of water is added dropwise to the dispersing liquid containing the surface-modified silica particles of the component (A) at a time while the dispersing liquid containing the surface-modified silica particles of the component (A) is heated. In addition, other examples thereof include a method in which the surface-modified silica particles of the component (A) are separated from the dispersing medium other than water, for example, by a combination of precipitation and separation, and/or centrifugation, followed by redispersing them in water.

The method for producing the surface-modified silica particles of the component (A) may further include other steps. Examples of the other steps include a step of filtrating a dispersing liquid containing the surface-modified silica particles of the component (A), a step of mixing a dispersing liquid containing the surface-modified silica particles of the component (A) and another additive, and/or a step of mixing other additives, followed by further filtration.

### (Modification Amount of Surface-Modifying Agent)

The surface-modified silica particles of the component (A) may be a silica particles modified by the surface-modifying agent. The modification amount of the surface-modifying agent in the surface-modified silica particles of the component (A) can be confirmed using a total organic carbon meter and a centrifugal separator. The details of this confirmation method are described in the Examples.

### (Structure of Surface-Modified Silica Particles)

The structure of the surface-modified silica particles of the component (A) can be confirmed by, for example, detecting the T2 component (the form of the formula (2) above) and/or the T3 component (the form of the formula (3) above) using 29Si-NMR. In the present specification, T means a Si atom having three bonds bound to an O atom and one bond bound (directly or indirectly bound) to a polyoxyalkylene chain, and each of the numbers of 2 and 3 means the number of Si—O—Si bonds in which the Si atom is involved. For example, the T2 component means a component having a Si atom involved in two Si—O—Si bonds among the Si atoms having three bonds bound to an O atom. In surface-unmodified silica particles, the T2 component and the T3 component bound (directly or indirectly bound) to a polyoxyalkylene chain are not detected, but in the surface-modified silica particles of the component (A), the T2 component and the T3 component are detected.

### [Component (B)]

The water of the component (B) is not particularly limited. In one embodiment, the component (B) is suitably used as a dispersing medium for dispersing the component (A). The component (B) may dissolve and/or disperse components other than the component (A). It is preferable that the polishing composition according to one embodiment contains a dispersing medium, and the dispersing medium contains the component (B). The polishing composition according to one embodiment may contain a dispersing medium, and the dispersing medium may consist of only the component (B). The water preferably contains as few impurities as possible in order to prevent contamination of an object to be polished and inhibition of the action of other components. As such water, for example, water having a total content of transition metal ions of 100 ppb or less is preferable. Here, the purity of the water can be increased by, for example, an operation such as removing impurity ions using an ion exchange resin, removing foreign matter using a filter, or distillation. Specifically, preferable examples of the water include deionized water (ion-exchanged water), pure water, ultrapure water, and distilled water, but are not particularly limited.

### [Component (C)]

The polishing composition according to one embodiment may further contain an acid as the component (C), or may not contain an acid as the component (C). The polishing composition according to one embodiment preferably further contains an acid as the component (C).

In one embodiment, the component (C) is suitably used as a pH adjusting agent. The polishing composition according to one embodiment preferably contains a pH adjusting agent. It is preferable that the polishing composition according to one embodiment contains a pH adjusting agent, and the pH adjusting agent contains the component (C). The polishing composition according to one embodiment may contain a pH adjusting agent, and the pH adjusting agent may consist of only the component (C).

The acid of the component (C) is not particularly limited. Examples of the acid include an organic acid and an inorganic acid, but are not particularly limited. Examples of the organic acid include an aliphatic carboxylic acid, an aromatic carboxylic acid, a hydroxy acid, an organic sulfonic acid, and an organic phosphonic acid, but are not particularly limited. Examples of the aliphatic carboxylic acid include an aliphatic monocarboxylic acid and an aliphatic dicarboxylic acid, but are not particularly limited. Examples of the aliphatic monocarboxylic acid include formic acid, acetic acid, and propionic acid, but are not particularly limited. Examples of the aliphatic dicarboxylic acid include maleic acid, fumaric acid, and succinic acid, but are not particularly limited. Examples of the aromatic carboxylic acid include benzoic acid and phthalic acid, but are not particularly limited. Examples of the hydroxy acid include citric acid, oxalic acid, tartaric acid, and malic acid, but are not particularly limited. Examples of the inorganic acid include sulfuric acid, nitric acid, hydrochloric acid, and carbonic acid, but are not particularly limited. These acids can be used singly or in combination of two or more thereof. The component (C) preferably contains at least one kind of acid selected from the group consisting of the acids exemplified above. The component (C) is preferably an inorganic acid, and particularly preferably nitric acid. As the component (C), a commercially available product may be used or a synthetic product may be used.

It is preferable that the polishing composition according to one embodiment further contains the component (C): an acid, and the acid contains an inorganic acid. It is more preferable that the polishing composition according to one embodiment further contains the component (C): an acid, and the acid contains nitric acid. It is still more preferable that the polishing composition according to one embodiment further contains the component (C): an acid, and the acid consists of only nitric acid.

When the polishing composition according to one embodiment contains the component (C), the content of the component (C) in the polishing composition is not particularly limited. The content of the component (C) is preferably such an amount that allows the polishing composition to exhibit a desired pH. The content of the component (C) is preferably 0.00001% by mass or more and 10% by mass or less, more preferably 0.0001% by mass or more and 10% by mass or less, still more preferably 0.001% by mass or more and 1% by mass or less, even still more preferably 0.005% by mass or more and 0.5% by mass or less, further still more preferably 0.01% by mass or more and 0.25% by mass or less, and particularly preferably 0.01% by mass or more and 0.1% by mass or less, relative to the total mass of the polishing composition. When the polishing composition according to one embodiment contains two or more kinds of acids as the component (C), the content of the component (C) represents the total content thereof.

### [Component (D)]

The polishing composition according to one embodiment may further contain a compound containing a polyoxyalkylene chain as the component (D), and may not contain a compound containing a polyoxyalkylene chain as the component (D). The polishing composition according to one embodiment preferably further contains a compound containing a polyoxyalkylene chain as the component (D).

In the present specification, the component (D) represents a component that exists separately from the surface-modifying group of the surface-modified silica particles of the component (A), in the polishing composition.

The polyoxyalkylene chain in the compound containing a polyoxyalkylene chain of the component (D) may be composed of one kind of oxyalkylene or may be composed of two or more kinds of oxyalkylenes. Examples of the polyoxyalkylene chain in the compound containing a polyoxyalkylene chain of the component (D) include a polyoxyethylene chain, a polyoxypropylene chain, a polyoxytrimethylene chain, a polyoxytetramethylene chain, a polyoxyisobutylene chain, a polyoxyethylene-polyoxypropylene chain, a polyoxyethylene-polyoxytetramethylene chain, and a polyoxyethylene-polyoxypropylene-polyoxyethylene chain, but are not particularly limited. When the polyoxyalkylene chain in the compound containing a polyoxyalkylene chain of the component (D) is composed of two or more kinds of oxyalkylens, the binding form of two or more kinds of oxyalkylenes may be random, alternating, block, periodic, or any combination thereof. The polyoxyalkylene chain in the compound containing a polyoxyalkylene chain of the component (D) preferably contains at least one kind of polyoxyalkylene chain selected from the group consisting of the polyoxyalkylene chains exemplified above. The polyoxyalkylene chain in the compound containing a polyoxyalkylene chain of the component (D) is preferably at least one kind selected from the group consisting of a polyoxyethylene chain, a polyoxypropylene chain, a polyoxyethylene-polyoxypropylene chain, and a polyoxyethylene-polyoxypropylene-polyoxyethylene chain, and more preferably a polyoxyethylene chain.

For example, the polyoxyalkylene chain in the compound containing a polyoxyalkylene chain of the component (D) may have a structure in which an end of the polyoxyalkylene chain is capped. For example, the polyoxyalkylene chain in the compound containing a polyoxyalkylene chain of the component (D) may have a structure in which one end or both ends of the polyoxyalkylene chain are capped with an aliphatic hydrocarbon group. That is, the hydrogen atom in the hydroxy group at one end or both ends of the polyoxyalkylene chain in the compound containing a polyoxyalkylene chain of the component (D) may be substituted with an aliphatic hydrocarbon group. Examples of the aliphatic hydrocarbon group that caps the end of the polyoxyalkylene chain in the compound containing a polyoxyalkylene chain of the component (D) include aliphatic hydrocarbon groups having 1 or more and 10 or less carbon atoms, but are not particularly limited. Examples of the aliphatic hydrocarbon group having 1 or more and 10 or less carbon atoms include a straight-chain or branched alkyl group, a straight-chain or branched alkenyl group, and an alkynyl group, but are not particularly limited. Examples of the straight-chain or branched alkyl group include a methyl group, an ethyl group, a n-propyl group, an isopropyl group, a n-butyl group, an isobutyl group, a sec-butyl group, a tert-butyl group, a pentyl group, a hexyl group, a heptyl group, an octyl group, a 2-ethylhexyl group, and a decyl group, but are not particularly limited. Examples of the straight-chain or branched alkenyl group include a vinyl group and an allyl group, but are not particularly limited. Examples of the alkynyl group include an ethynyl group and a propynyl group, but are not particularly limited.

In one embodiment, the component (D): the compound containing a polyoxyalkylene chain preferably contains polyalkylene glycol, a compound having a structure in which one end of the polyoxyalkylene chain is capped, a compound having a structure in which both ends of the polyoxyalkylene chain are capped, or a combination thereof, and is more preferably polyalkylene glycol, a compound having a structure in which one end of the polyoxyalkylene chain is capped, a compound having a structure in which both ends of the polyoxyalkylene chain are capped, or a combination thereof.

Specific examples of the component (D) include polyethylene glycol, polypropylene glycol, polytrimethylene glycol, polytetramethylene glycol, polyisobutylene glycol, an ethylene glycol-propylene glycol copolymer, and an ethylene glycol-tetramethylene glycol copolymer, but are not particularly limited. Note that, the binding form of the copolymer may be random, alternating, block, periodic, or any combination thereof. These compounds containing a polyoxyalkylene chain can be used singly or in combination of two or more thereof. The component (D) preferably contains at least one kind of compound containing a polyoxyalkylene chain selected from the group consisting of the compounds containing a polyoxyalkylene chain exemplified above. The component (D) is preferably polyalkylene glycol, more preferably at least one compound selected from the group consisting of polyethylene glycol, polypropylene glycol, and a polyethylene glycol-polypropylene glycol copolymer, and still more preferably polyethylene glycol.

It is preferable that the polishing composition according to one embodiment further contains the component (D): the compound containing a polyoxyalkylene chain, and the compound containing a polyoxyalkylene chain contains polyalkylene glycol. It is more preferable that the polishing composition according to one embodiment further contains the component (D): the compound containing a polyoxyalkylene chain, and the compound containing a polyoxyalkylene chain contains polyethylene glycol. It is still more preferable that the polishing composition according to one embodiment further contains the component (D): the compound containing a polyoxyalkylene chain, and the compound containing a polyoxyalkylene chain consists of only polyethylene glycol.

The weight average molecular weight (Mw) of the compound containing a polyoxyalkylene chain of the component (D) is not particularly limited. The lower limit of the weight average molecular weight of the compound containing a polyoxyalkylene chain of the component (D) is preferably 80 or more, more preferably 100 or more, still more preferably 200 or more, and particularly preferably 300 or more. The upper limit of the weight average molecular weight of the compound containing a polyoxyalkylene chain of the component (D) is preferably 1,000,000 or less, more preferably 100,000 or less, still more preferably 10,000 or less, and particularly preferably less than 1,000. In one embodiment, examples of the weight average molecular weight of the compound containing a polyoxyalkylene chain of the component (D) include 80 or more and 1,000,000 or less, 100 or more and 100,000 or less, 200 or more and 10,000 or less, and 300 or more and less than 1,000, but are not particularly limited. The weight average molecular weight of the compound containing a polyoxyalkylene chain can be measured by gel permeation chromatography (GPC) using polyethylene glycol as a standard substance.

As the component (D), a commercially available product may be used or a synthesized product may be used.

When the polishing composition according to one embodiment contains the component (D), the content of the component (D) in the polishing composition is not particularly limited. The content of the component (D) is preferably 0.0001% by mass or more and 1% by mass or less, more preferably 0.0005% by mass or more and 0.1% by mass or less, and still more preferably 0.001% by mass or more and 0.01% by mass or less, relative to the total mass of the polishing composition. When the polishing composition according to one embodiment contains two or more kinds of compounds containing a polyoxyalkylene chain as the component (D), the content of the component (D) represents the total content thereof.

### [Compound (E)]

The polishing composition according to one embodiment may further contain a salt compound as the component (E), and may not contain a salt compound as the component (E). The polishing composition according to one embodiment preferably further contains a salt compound as the component (E).

In one embodiment, the component (E) can be suitably used as an electrical conductivity adjusting agent. The polishing composition according to one embodiment preferably contains an electrical conductivity adjusting agent. It is preferable that the polishing composition according to one embodiment contains an electrical conductivity adjusting agent, and the electrical conductivity adjusting agent contains the component (E). The polishing composition according to one embodiment may contain an electrical conductivity adjusting agent, and the electrical conductivity adjusting agent may consist of only the component (E).

The salt compound may be an acid salt, a base salt, or a combination thereof. The salt compound may be an organic salt compound, an inorganic salt compound, or a combination thereof. Examples of the salt compound include potassium nitrate, ammonium nitrate, potassium bicarbonate, ammonium carbonate, ammonium hydrogen carbonate, diammonium hydrogenphosphate, ammonium dihydrogenphosphate, ammonium sulfate, potassium chloride, sodium chloride, potassium bromide, potassium iodide, ammonium citrate, potassium hydroxide, sodium hydroxide, tetramethylammonium hydroxide, and tetraethylammonium hydroxide, but are not particularly limited. These salt compounds can be used singly or in combination of two or more thereof. The component (E) preferably contains at least one kind of salt compound selected from the group consisting of the salt compounds exemplified above. It is preferable that the component (E) is not a hydroxide. The component (E) is preferably an inorganic salt compound, and particularly preferably ammonium sulfate. As the component (E), a commercially available product may be used or a synthesized product may be used.

It is preferable that the polishing composition according to one embodiment further contains the component (E): the salt compound, and the salt compound contains an inorganic salt compound. It is more preferable that the polishing composition according to one embodiment further contains the component (E): the salt compound, and the salt compound contains ammonium sulfate. It is still preferable that the polishing composition according to one embodiment further contains the component (E): the salt compound, and the salt compound consists of only the ammonium sulfate.

When the polishing composition according to one embodiment contains the component (E), the content of the component (E) in the polishing composition is not particularly limited. The content of the component (E) is preferably 0.01% by mass or more and 7.5% by mass or less, more preferably 0.1% by mass or more and 5% by mass or less, and still more preferably 1% by mass or more and 5% by mass or less, relative to the total mass of the polishing composition. When the polishing composition according to one embodiment contains two or more kinds of salt compounds as the component (E), the content of the component (E) represents the total content thereof.

### (Other Components)

The polishing composition according to one embodiment may further contain one kind or two or more kinds of other components (components other than the component (A) to component (E)) if necessary. Therefore, the polishing composition according to one embodiment may further contain or may not contain one kind or two or more kinds of other components. The other components may be a known additive that can be used in the polishing composition. Examples of the other components include a water-soluble polymer (note that, the compound containing a polyoxyalkylene chain is excluded), a pH adjusting agent (note that, an acid is excluded), an oxidizing agent, a complexing agent, an antiseptic agent, an antifungal agent, a electrical conductivity adjusting agent (note that, a salt compound is excluded), and an organic solvent, but are not particularly limited. The substances constituting these other components can be each independently used alone or in combination of two or more kinds thereof.

### (Examples of Compositions of Preferable Polishing Compositions)

A polishing composition according to one preferable embodiment may substantially consist of:
component (A);
component (B); and
component (C).

A polishing composition according to one preferable embodiment may substantially consist of:
component (A);
component (B);
component (C); and
at least one component selected from the group consisting of component (D) and component (E).

A polishing composition according to one preferable embodiment may substantially consist of:
component (A);
component (B);
component (C); and
at least one kind of component selected from the group consisting of water-soluble polymer (note that, compound containing a polyoxyalkylene chain is excluded), pH adjusting agent (note that, acid is excluded), oxidizing agent, complexing agent, antiseptic agent, antifungal agent, electrical conductivity adjusting agent (note that, salt compound is excluded), and organic solvent.

A polishing composition according to one preferable embodiment may substantially consist of:
component (A);
component (B);
component (C);
at least one component selected from the group consisting of component (D) and component (E); and
at least one kind of component selected from the group consisting of water-soluble polymer (note that, compound containing a polyoxyalkylene chain is excluded), pH adjusting agent (note that, acid is excluded), oxidizing agent, complexing agent, antiseptic agent, antifungal agent, electrical conductivity adjusting agent (note that, salt compound is excluded), and organic solvent.

In these embodiments, “the polishing composition substantially consists of X” means that the total content of X is more than 99% by mass (upper limit: 100% by mass) relative to the total mass of the polishing composition. The polishing composition according to one preferable embodiment consists of only X (the total content=100% by mass).

A polishing composition according to one preferable embodiment may consist of only:
component (A);
component (B); and
component (C).

A polishing composition according to one preferable embodiment may consist of only: component (A);
component (B);
component (C); and
at least one component selected from the group consisting of component (D) and component (E).

A polishing composition according to one preferable embodiment may consist of only:
component (A);
component (B);
component (C); and
at least one kind of component selected from the group consisting of water-soluble polymer (note that, compound containing a polyoxyalkylene chain is excluded), pH adjusting agent (note that, acid is excluded), oxidizing agent, complexing agent, antiseptic agent, antifungal agent, electrical conductivity adjusting agent (note that, salt compound is excluded), and organic solvent.

A polishing composition according to one preferable embodiment may consist of only: component (A);
component (B);
component (C);
at least one component selected from the group consisting of component (D) and component (E); and
at least one kind of component selected from the group consisting of water-soluble polymer (note that, compound containing a polyoxyalkylene chain is excluded), pH adjusting agent (note that, acid is excluded), oxidizing agent, complexing agent, antiseptic agent, antifungal agent, electrical conductivity adjusting agent (note that, salt compound is excluded), and organic solvent.

Here, the polishing composition according to the present aspect is not limited thereto.

### (pH of Polishing Composition)

The pH of the polishing composition according to one embodiment is not particularly limited as long as it is less than 7. Since a ratio of a polishing removal rate of a material having a silicon-silicon bond to a polishing removal rate of a material having an oxygen-silicon bond tends to have a better range, the upper limit of the pH of the polishing composition according to one embodiment is preferably 6 or less, and more preferably less than 6. Since a ratio of a polishing removal rate of a material having a silicon-silicon bond to a polishing removal rate of a material having a nitrogen-silicon bond tends to have a better range, the upper limit of the pH of the polishing composition according to one embodiment is more preferably 5 or less, still more preferably 4 or less, and particularly preferably 3 or less. Since a polishing removal rate of a material having a silicon-silicon bond tends to be further improved, the lower limit of the pH of the polishing composition according to one embodiment is preferably 1 or more, more preferably 1.5 or more, and still more preferably 2 or more. Examples of the range of the pH of the polishing composition according to one embodiment include 1 or more and less than 7, 1 or more and less than 6, 1 or more and 6 or less, 1 or more and 5 or less, 1 or more and 4 or less, 1 or more and 3 or less, 1.5 or more and less than 7, 1.5 or more and less than 6, 1.5 or more and 6 or less, 1.5 or more and 5 or less, 1.5 or more and 4 or less, 1.5 or more and 3 or less, 2 or more and less than 7, 2 or more and 6 or less, 2 or more and 5 or less, 2 or more and 4 or less, and 2 or more and 3 or less, but are not particularly limited. The pH value of the polishing composition can be confirmed by a pH meter. The details of the method for measuring the pH will be described in Examples.

### (Electrical Conductivity of Polishing Composition)

The electrical conductivity of the polishing composition according to one embodiment is not particularly limited. The electrical conductivity of the polishing composition according to one embodiment is preferably 0.1 mS/cm or more, more preferably 0.5 mS/cm or more, still more preferably 1 mS/cm or more, even still more preferably 1.5 mS/cm or more, and particularly preferably 2 mS/cm or more. The electrical conductivity is preferably 20 mS/cm or less, more preferably 15 mS/cm or less, still more preferably 10 mS/cm or less, even still more preferably 8 mS/cm or less, further still more preferably 6 mS/cm or less, and particularly preferably 4 mS/cm or less. The electrical conductivity may be 3.5 mS/cm or less, and may be, for example, 2 mS/cm or less. Within such ranges, the repulsion between abrasive grains can be appropriately adjusted and stability can be ensured. Examples of the range of the electrical conductivity of the polishing composition according to one embodiment include 0.1 mS/cm or more and 20 mS/cm or less, 0.5 mS/cm or more and 15 mS/cm or less, 0.5 mS/cm or more and 10 mS/cm or less, 1 mS/cm or more and 10 mS/cm or less, 1.5 mS/cm or more and 8 mS/cm or less, 2 mS/cm or more and 6 mS/cm or less, 2 mS/cm or more and 4 mS/cm or less, 2 mS/cm or more and 3.5 mS/cm or less, more than 0 mS/cm and 3.5 mS/cm or less, and more than 0 mS/cm and 2.0 mS/cm or less, but are not particularly limited. The electrical conductivity of the polishing composition can be measured using an electrical conductivity meter. The details of the method for measuring the electrical conductivity will be described in Examples. The electrical conductivity can be adjusted by the kind and content of the polishing composition, for example, by the kind and content of the electrical conductivity adjusting agent.

### (Form of Polishing Composition)

The polishing composition according to one embodiment may be a one-component type or a multi-component type consisting of two or more components. The polishing composition according to one embodiment may be used for polishing as it is. The polishing composition according to one embodiment may be obtained by, for example, a method including adding the component (B) anew or adding a further amount of the component (B) to a concentrated solution of the polishing composition to dilute the concentrated solution. The polishing composition according to one embodiment may be, for example, a concentrated solution of the polishing composition.

### (Method for Producing Polishing Composition)

The method for producing the polishing composition according to one embodiment is not particularly limited. Examples of the method for producing the polishing composition according to one embodiment include a method including: mixing the component (A), the component (B), the component (C) if necessary, the component (D) if necessary, the component (E) if necessary, and one kind or two or more kinds of other components if necessary. The method for producing the polishing composition according to one embodiment is preferably a method including: producing the component (A) by the method for producing the surface-modified silica particles (preferably the method of the (a1) or the (b1), and more preferably the method of the (a1)); and mixing the component (A), the component (B), the component (C) if necessary, the component (D) if necessary, the component (E) if necessary, and one kind or two or more kinds of other components if necessary.

### (Object to be Polished)

An object polished using the polishing composition according to one embodiment (object to be polished) is not particularly limited. The object to be polished may be composed of only one kind of material, or may be a combination of two or more kinds of materials. The polishing composition according to one embodiment is suitably used for polishing the object to be polished that contains at least one kind of material selected from the group consisting of a material having a silicon-silicon bond, a material having an oxygen-silicon bond, and a material having a nitrogen-silicon bond. The object to be polished may further contain one kind or two or more kinds of other materials, in addition to at least one kind of material selected from the group consisting of the material having a silicon-silicon bond, the material having an oxygen-silicon bond, and the material having a nitrogen-silicon bond. Examples of the other materials include a metal and a resin, but are not particularly limited. The polishing composition according to one embodiment is preferably used for polishing the object to be polished that contains the material having an oxygen-silicon bond and the material having a silicon-silicon bond. For example, the polishing composition according to one embodiment is preferably used for polishing the object to be polished that contains a layer having an oxygen-silicon bond and a layer having a silicon-silicon bond. The polishing composition according to one embodiment may be used for polishing the object to be polished that contains the material having an oxygen-silicon bond, the material having a nitrogen-silicon bond, and the material having a silicon-silicon bond. For example, the polishing composition according to one embodiment may be used for polishing the object to be polished that contains a layer having an oxygen-silicon bond, a layer having a nitrogen-silicon bond, and a layer having a silicon-silicon bond. An effect of achieving a high polishing removal rate of the material having a silicon-silicon bond is focused, and the polishing composition according to one embodiment may be used for polishing the object to be polished that contains the material having a silicon-silicon bond. The polishing composition according to one embodiment may be used for polishing the object to be polished that contains the material having a nitrogen-silicon bond, the material having a silicon-silicon bond, or a combination thereof.

Examples of the material having a silicon-silicon bond include single crystal silicon, polycrystal silicon (polysilicon), amorphous silicon, n-type doped single crystal silicon, p-type doped single crystal silicon, and a Si-based alloy, but are not particularly limited. Examples of the material having an oxygen-silicon bond include silicon oxide, but are not particularly limited. Examples of the material having an oxygen-silicon bond include TEOS-type silicon oxide generated by using tetraethyl orthosilicate as a precursor (simply also referred to as “TEOS” in the present specification), HDP (high density plasma), USG (undoped silicate glass), PSG (phosphorus silicate glass), BPSG (boron-phospho silicate glass), and RTO (rapid thermal oxidation), but are not particularly limited. Examples of the material having a nitrogen-silicon bond include silicon nitride and silicon carbonitride (SiCN), but are not particularly limited. These materials may be used alone or in combination of two or more kinds thereof. The object to be polished preferably contains at least one kind of material selected from the group consisting of the materials exemplified above. The object to be polished preferably contains polysilicon, more preferably contains silicon oxide and polysilicon, and still more preferably contains TEOS and polysilicon. The object to be polished may contain silicon oxide, silicon nitride, and polysilicon, and may contain TEOS, silicon nitride, and polysilicon.

A ratio of a polishing removal rate of the material having a silicon-silicon bond (preferably, polysilicon. Hereinafter, the same applies in the present paragraph.) to a polishing removal rate of the material having an oxygen-silicon bond (preferably, silicon oxide, and more preferably TEOS. Hereinafter, the same applies in the present paragraph.) (polishing removal rate of the material having a silicon-silicon bond/polishing removal rate of the material having an oxygen-silicon bond) is not particularly limited. The polishing composition in one embodiment preferably has such a characteristic that the ratio of the polishing removal rate of the material having a silicon-silicon bond to the polishing removal rate of the material having an oxygen-silicon bond is 0.50 or more and 2.00 or less. The ratio of the polishing removal rate of the material having a silicon-silicon bond to the polishing removal rate of the material having an oxygen-silicon bond is more preferably 0.80 or more and 1.90 or less, and still more preferably 0.90 or more and 1.90 or less. There are preferable cases where the polishing removal rate of the material having a silicon-silicon bond is the same as the polishing removal rate of the material having an oxygen-silicon bond or is slightly higher than the polishing removal rate of the material having an oxygen-silicon bond. The ratio of the polishing removal rate of the material having a silicon-silicon bond to the polishing removal rate of the material having an oxygen-silicon bond is more preferably 1.00 or more and 1.80 or less, still more preferably 1.10 or more and 1.80 or less, even still more preferably 1.10 or more and 1.70 or less, further more preferably 1.20 or more and 1.60 or less, further more preferably 1.20 or more and 1.50 or less, and particularly preferably 1.30 or more and 1.50 or less.

A ratio of the polishing removal rate of the material having a silicon-silicon bond (preferably, polysilicon. Hereinafter, the same applies in the present paragraph.) to the polishing removal rate of the material having a nitrogen-silicon bond (preferably, silicon nitride. Hereinafter, the same applies in the present paragraph.) (polishing removal rate of the material having a silicon-silicon bond/polishing removal rate of the material having a nitrogen-silicon bond) is not particularly limited. In the polishing composition according to one embodiment, there are preferable cases where the polishing removal rate of the material having a silicon-silicon bond is higher than the polishing removal rate of the material having a nitrogen-silicon bond, to the extent that the polishing removal rate of the material having a silicon-silicon bond is not excessively high. It preferably has such a characteristic that a ratio of the polishing removal rate of the material having a silicon-silicon bond to the polishing removal rate of the material having a nitrogen-silicon bond is preferably 2.50 or more and 10.00 or less. The ratio of the polishing removal rate of the material having a silicon-silicon bond to the polishing removal rate of the material having a nitrogen-silicon bond is more preferably 2.50 or more and 9.00 or less, still more preferably 3.00 or more and 8.50 or less, even still more preferably 3.00 or more and 8.00 or less, further more preferably 4.00 or more and 7.50 or less, further more preferably 5.00 or more and 7.50 or less, further more preferably 6.00 or more and 7.00 or less, and particularly preferably 6.20 or more and 6.80 or less.

### <Polishing Method and Method for Producing Semiconductor Substrate>

One another aspect of the present disclosure relates to a polishing method including polishing an object to be polished by using the polishing composition according to the above aspect.

In accordance with the polishing method according to one embodiment of the present disclosure including such a configuration, it is possible to achieve a high polishing removal rate of a material having a silicon-silicon bond and satisfy a ratio of a polishing removal rate of the material having a silicon-silicon bond to a polishing removal rate of a material having an oxygen-silicon bond within a good range, when the pH of a polishing composition is less than 7.

The object to be polished in the present aspect is also the same as the explanation of the object to be polished to which the polishing composition according to the above aspect is applied.

In the polishing method according to one embodiment, the object to be polished preferably contains the material having an oxygen-silicon bond and the material having a silicon-silicon bond. For example, in the polishing method according to one embodiment, the object to be polished preferably contains a layer having an oxygen-silicon bond and a layer having a silicon-silicon bond. In the polishing method according to one embodiment, the object to be polished may contain the material having an oxygen-silicon bond, the material having a nitrogen-silicon bond and the material having a silicon-silicon bond. For example, in the polishing method according to one embodiment, the object to be polished may contain a layer having an oxygen-silicon bond, a layer having a nitrogen-silicon bond, and a layer having a silicon-silicon bond. In the polishing method according to one embodiment, an effect of achieving a high polishing removal rate of the material having a silicon-silicon bond by the polishing composition according to the above aspect is focused, and the object to be polished may contain the material having a silicon-silicon bond. In the polishing method according to one embodiment, the object to be polished may contain the material having a nitrogen-silicon bond, the material having a silicon-silicon bond, or a combination thereof. As examples of the material having a silicon-silicon bond, the examples of the material having an oxygen-silicon bond, and examples of the material having a nitrogen-silicon bond, the same exemplified in the explanation of the above object to be polished are each exemplified. In the polishing method according to one preferable embodiment, the object to be polished preferably contains polysilicon, more preferably contains silicon oxide and polysilicon, and still more preferably contains TEOS and polysilicon. In the polishing method according to one embodiment, the object to be polished may contain silicon oxide, silicon nitride, and polysilicon, and may contain TEOS, silicon nitride, and polysilicon.

A ratio of a polishing removal rate of the material having a silicon-silicon bond (preferably, polysilicon. Hereinafter, the same applies in the present paragraph.) to a polishing removal rate of the material having an oxygen-silicon bond (preferably, silicon oxide, and more preferably TEOS. Hereinafter, the same applies in the present paragraph.) (polishing removal rate of the material having a silicon-silicon bond/polishing removal rate of the material having an oxygen-silicon bond) is not particularly limited. In the polishing method according to one embodiment, the ratio of the polishing removal rate of the material having a silicon-silicon bond to the polishing removal rate of the material having an oxygen-silicon bond is preferably 0.50 or more and 2.00 or less. The ratio of the polishing removal rate of the material having a silicon-silicon bond to the polishing removal rate of the material having an oxygen-silicon bond is more preferably 0.80 or more and 1.90 or less, and still more preferably 0.90 or more and 1.90 or less. There are preferable cases where the polishing removal rate of the material having a silicon-silicon bond is the same as the polishing removal rate of the material having an oxygen-silicon bond or is slightly higher than the polishing removal rate of the material having an oxygen-silicon bond. The ratio of the polishing removal rate of the material having a silicon-silicon bond to the polishing removal rate of the material having an oxygen-silicon bond is more preferably 1.00 or more and 1.80 or less, still more preferably 1.10 or more and 1.80 or less, even still more preferably 1.10 or more and 1.70 or less, further more preferably 1.20 or more and 1.60 or less, further more preferably 1.20 or more and 1.50 or less, and particularly preferably 1.30 or more and 1.50 or less.

A ratio of the polishing removal rate of the material having a silicon-silicon bond (preferably, polysilicon. Hereinafter, the same applies in the present paragraph.) to the polishing removal rate of the material having a nitrogen-silicon bond (preferably, silicon nitride. Hereinafter, the same applies in the present paragraph.) (polishing removal rate of the material having a silicon-silicon bond/polishing removal rate of the material having a nitrogen-silicon bond) is not particularly limited. There are preferable cases where the polishing removal rate of the material having a silicon-silicon bond is higher than the polishing removal rate of the material having a nitrogen-silicon bond, to the extent that the polishing removal rate of the material having a silicon-silicon bond is not excessively high. In the polishing method according to one embodiment, a ratio of the polishing removal rate of the material having a silicon-silicon bond to the polishing removal rate of the material having a nitrogen-silicon bond is preferably 2.50 or more and 10.00 or less, more preferably 2.50 or more and 9.00 or less, still more preferably 3.00 or more and 8.50 or less, even still more preferably 3.00 or more and 8.00 or less, further more preferably 4.00 or more and 7.50 or less, further more preferably 5.00 or more and 7.50 or less, further more preferably 6.00 or more and 7.00 or less, and particularly preferably 6.20 or more and 6.80 or less.

Another aspect of the present disclosure relates to a method for producing a semiconductor substrate containing an object to be polished, the method including polishing the object to be polished by the polishing method according to the above aspect. The object to be polished in the present aspect is also the same as the explanation of the object to be polished to which the polishing composition according to the above aspect is applied.

The polishing device is not particularly limited. As an example of the polishing device, a general polishing device, which is equipped with a holder that holds a substrate containing an object to be polished, and a motor capable of changing the number of revolutions, and which has a polishing table to which a polishing pad (polishing cloth) can be attached, can be used.

The polishing pad is not particularly limited. Examples of the material of the polishing pad include nonwoven fabric, polyurethane, and porous fluororesin, but are not particularly limited. The polishing pad is preferably subjected to groove processing so that a polishing liquid can be collected.

The polishing conditions are not particularly limited. For example, the speed of revolutions (number of revolutions) of the polishing table is preferably 10 rpm (0.17 s⁻¹) or more and 500 rpm (8.33 s⁻¹) or less. For example, the speed of revolutions (number of revolutions) of a head is preferably 10 rpm (0.17 s⁻¹) or more and 500 rpm (8.33 s⁻¹) or less. For example, the pressure (polishing pressure) applied to the substrate having the object to be polished (the substrate containing the object to be polished) is preferably 0.5 psi (3.4 kPa) or more and 10 psi (68.9 kPa) or less. A method for supplying the polishing composition to the polishing pad is also not particularly limited, and, for example, a continuously supplying method with, for example, a pump can be employed. This supplying amount is not limited, and it is preferable that the surface of the polishing pad is always covered with the polishing composition. The polishing time is not particularly limited, and, for example, the time for which the desired polishing can be achieved may be appropriately selected.

After completion of the polishing, the substrate containing the object to be polished may be cleaned with running water, and water droplets adhering to the substrate may be removed and dried using a spin dryer or the like.

Although the embodiments of the present disclosure have been described in detail, it is apparent that this is merely illustrative and exemplary and is not limiting, and the scope of the present disclosure should be interpreted by the appended scope of claims.

The present disclosure encompasses, but is not limited to, the following aspects and embodiments:
[1] A polishing composition containing the following component (A) and the following component (B) and having a pH of less than 7:
component (A): surface-modified silica particles containing silica particles and a surface-modifying group that modifies a surface of the silica particles and contains a polyoxyalkylene chain having a weight average molecular weight of 80 or more and 7,000 or less; and
component (B): water;
[2] The polishing composition according to [1], wherein a weight average molecular weight of the polyoxyalkylene chain is 80 or more and 600 or less;
[3] The polishing composition according to [1] or [2], wherein the component (A) contains silica particles containing a compound containing a polyoxyalkylene chain fixed on a surface of the particles through a silane coupling agent;
[4] The polishing composition according to [3], wherein the compound containing a polyoxyalkylene chain is a compound composed of only a polyalkylene glycol chain;
[5] The polishing composition according to [4], wherein the compound composed of only a polyalkylene glycol chain is at least one compound selected from the group consisting of polyethylene glycol, polypropylene glycol, and a polyethylene glycol-polypropylene glycol copolymer;
[6] The polishing composition according to any one of [3] to [5], wherein the silane coupling agent contains an isocyanate group-containing silane coupling agent;
[7] The polishing composition according to any one of [1] to [6], wherein the pH is 1 or more and less than 6;
[8] The polishing composition according to any one of [1] to [7], wherein the polishing composition has electrical conductivity of 0.5 mS/cm or more and 10 mS/cm or less;
[9] The polishing composition according to any one of [1] to [8], wherein the polishing composition has such a characteristic that a ratio of a polishing removal rate of a material having a silicon-silicon bond to a polishing removal rate of a material having an oxygen-silicon bond (polishing removal rate of the material having a silicon-silicon bond/polishing removal rate of the material having an oxygen-silicon bond) is 0.50 or more and 2.00 or less;
[10] The polishing composition according to any one of [1] to [9], which is used for polishing an object to be polished containing a material having an oxygen-silicon bond and a material having a silicon-silicon bond;
[11] A polishing method, including polishing an object to be polished containing a material having an oxygen-silicon bond and a material having a silicon-silicon bond by using the polishing composition according to any one of [1] to [10]; and
[12] The polishing method according to [11], wherein a ratio of a polishing removal rate of the material having a silicon-silicon bond to a polishing removal rate of the material having an oxygen-silicon bond (polishing removal rate of the material having a silicon-silicon bond/polishing removal rate of the material having an oxygen-silicon bond) is 0.50 or more and 2.00 or less.

### EXAMPLES

The present disclosure will be described in more detail using the following Examples and Comparative Examples. However, the technical scope of the present disclosure is not limited to only the following Examples. Unless otherwise specified, “%” and “part(s)” mean “% by mass” and “part(s) by mass”, respectively.

### <Production of Surface-Modified Silica Particle>

### Production Example 1

36.3 g of polyethylene glycol 1 was distributed to a 100 mL airtight heat-resistant container, and the container was placed on a hot stirrer at 80° C. The lid was removed and stirring was performed at 100 rpm using a stirrer. During stirring, 18.7 g of 3-isocyanate propyl trimethoxysilane was added at a rate of 0.03 g/sec so that the molar ratio between polyethylene glycol 1 and 3-isocyanate propyl trimethoxysilane was 1:1. After 3-isocyanate propyl trimethoxysilane was added, the container was sealed and stirring was continued for another 30 minutes at 100 rpm. The stirrer was removed, the container was sealed again, and the container was returned to an air bath having an atmosphere of 80° C. (the container was placed into an air bath having an atmosphere of 80° C.) and was warmed until the peak of the isocyanate group derived from the silane coupling agent at about 2,260 cm⁻¹ disappeared in the FT-IR spectrum. As the warming time, warming was performed for 26 hours in total, and the target surface-modifying agent 1 was obtained.

Separately, 4,500 g of an aqueous solution of a high-purity colloidal silica (average secondary particle size: 70 nm, synthesized by the sol-gel method) having a concentration of 5% by mass, which was collected in a 5,000 mL flask, was provided and was warmed to a liquid temperature of 80° C. using a mantle heater. After the temperature reached 80° C., 50.8 g of the surface-modifying agent 1 obtained above was weighed and added at a rate of 0.03 g/sec while this solution was stirred at 150 rpm. Furthermore, while the liquid temperature was maintained at 80° C. using a mantle heater, stirring was performed at 150 rpm for 30 minutes. Then, the mixture was transferred to an airtight container, and was sealed. Then, the airtight container was returned to an air bath having an atmosphere of 80° C. (the airtight container was placed into an air bath having an atmosphere of 80° C.) and was warmed for 26 hours to obtain the desired surface-modified colloidal silica 1.

### Production Examples 2 to 9

As described in Table 1, each of the desired surface-modified colloidal silicas 2 to 9 was obtained in the same manner as in Example 1, except that polyethylene glycol 1 was changed to ethylene glycol, polyethylene glycol 2, polyethylene glycol 3, polyethylene glycol 4, polyethylene glycol 5, polyethylene glycol 6, polyethylene glycol 7, or polyethylene glycol 8.

The details of the surface-modified colloidal silicas and an alkylene glycol or compounds containing a polyoxyalkylene chain, used for its production, are shown in Table 1.

### (Average Secondary Particle Size of Silica Particles)

The average secondary particle size of silica particles was evaluated by measuring an aqueous solution of a high-purity colloidal silica having a concentration of 5% by mass, using the dynamic light scattering method, represented by the laser diffraction scattering method.

### (Confirming Structure of Surface-Modifying Agent)

The structure of the surface-modifying agent 1 obtained above was confirmed using the following FT-IR device.

Device used: Fourier transform infrared spectroscopic analysis device (Spectrum100, available from PerkinElmer)

Detection method: ATR (Attenuated Total Reflection, total reflection measurement) method.

Specifically, 10 minutes after the addition of 3-isocyanate propyl trimethoxysilane of Production Example 1, 1 g was sampled from the reaction system. The obtained sample was placed on the ATR measurement crystal of Spectrum 100 and the FT-IR spectrum was measured. As a result, it could be confirmed that the peak of the isocyanate group derived from the silane coupling agent existed at about 2,260 cm⁻¹.

Furthermore, at the time when the reaction was completed, 1 g was sampled from the reaction system. The obtained sample was placed on the ATR crystal of Spectrum 100 and the FT-IR spectrum was measured. As a result, it could be confirmed that the peak of the isocyanate group derived from the silane coupling agent disappeared at about 2,260 cm⁻¹. This could confirm that the surface-modifying agent 1, in which the compound containing a polyoxyalkylene chain and the silane coupling agent were bound, was produced.

In the surface-modifying agents 2 to 9 obtained in the above Production Examples 2 to 9, using the FT-IR device in the same manner, it can be confirmed that the surface-modifying agent 2, in which alkylene glycol and the silane coupling agent are bound, and the surface-modifying agents 3 to 9, in which the compound containing a polyoxyalkylene chain and the silane coupling agent are bound, are each produced.

### (Modification Amount of Surface-Modifying Agent to Colloidal Silica in Surface-Modified Colloidal Silica)

The modification amount of the surface-modifying agent was confirmed for surface-modified colloidal silica 1 obtained above, using the following total organic carbon meter and the following centrifugal separator. Specifically, the surface-modified colloidal silica 1 was diluted with water so that a silica concentration was 0.175% by mass, to prepare a diluted solution, and calculation was performed by subtracting the TOC value of the supernatant after centrifugation from the TOC value of this diluted solution (i.e., the calculation of the TOC value of the diluted solution—the TOC value of the supernatant after centrifugation was performed). As a result, it was confirmed that the colloidal silica was modified by 8.4% by mass of the surface-modifying agent 1 relative to the mass of the silica.

The modification amounts of the surface-modifying agents for the surface-modified colloidal silicas 2 to 9 obtained above can be confirmed in the same manner using the following total organic carbon meter and the following centrifugal separator described below.

### <<Total Organic Carbon Meter>>

Device used: TOC-L_{CPH} (available from Shimadzu Corporation),
Measurement method: 680° C. combustion catalytic oxidation/NDIR detection.

### <<Centrifugal Separator>>

Device used: Avanti HP-30I (Beckman Coulter Inc.),
Number of revolutions: 26,000 rpm,
Centrifugation time: 30 minutes.

By confirming the structure of the surface-modified colloidal silica, using 29Si-NMR, it can be confirmed that the desired surface-modified colloidal silica has been obtained by the method of the Production Examples.

TABLE 1
Surface-modified colloidal silicas and alkylene glycol or compounds
containing polyoxyalkylene chain, used for its production

| | Surface-modifying agent used for producing | |
|---|---|---|
| | surface-modified colloidal silica | |
| Surface- | | Alkylene glycol or compound containing |
| modified | | polyoxyalkylene chain, used for |
| colloidal | | synthesizing surface-modifying agent |

| silicas | | | Weight average |
|---|---|---|---|
| No. | No. | Kind | molecular weight |
| 1 | 1 | Polyethylene glycol 1 | 414 |
| 2 | 2 | Ethylene glycol | 62 |
| 3 | 3 | Polyethylene glycol 2 | 106 |
| | | (diethylene glycol) | |
| 4 | 4 | Polyethylene glycol 3 | 150 |
| | | (triethylene glycol) | |
| 5 | 5 | Polyethylene glycol 4 | 194 |
| 6 | 6 | Polyethylene glycol 5 | 591 |
| 7 | 7 | Polyethylene glycol 6 | 1560 |
| 8 | 8 | Polyethylene glycol 7 | 6009 |
| 9 | 9 | Polyethylene glycol 8 | 10018 |

### <Production of Polishing Composition>

### Examples 1 to 10 and Comparative Examples 1 to 5

As described in Table 2, silica particles, an acid or a base, water, a compound containing an oxyalkylene chain if necessary, and a salt compound if necessary were mixed to obtain each of the polishing compositions of Examples 1 to 10 and Comparative Example 1 to 5.

In Table 2, the unmodified colloidal silica represents colloidal silica (average secondary particle size: 70 nm, synthesized by the sol-gel method). As the unmodified colloidal silica, the same colloidal silica as that used as a raw material of the surface-modified silica particles in the production of the surface-modified silica particles were used. In Table 2, the polyethylene glycol 1 represents the same kind of polyethylene glycol as the polyethylene glycol 1 used in the production of the surface-modified colloidal silica.

In Table 2, the contents of the silica particles, the acid or the base, the compound containing a polyoxyalkylene chain, and the salt compound are each represented as the content (% by mass) relative to the total mass of the polishing composition.

In Table 2, the components marked with “-” in the columns of the kind and the content indicate that the component was not added.

### <Evaluation of Polishing Composition>

### (pH of Polishing Composition)

The pH of the polishing composition was confirmed by a pH meter (available from HORIBA, Ltd., Product Name: LAQUA (Registered trademark)).

### (Electrical Conductivity of Polishing Composition)

The electrical conductivity (EC) of the polishing composition was measured by a desk top type electrical conductivity meter (available from HORIBA, Ltd., model number: DS-71 LAQUA (Registered trademark)).

### (Polishing Performance)

The polishing composition was used to polish the surface of an object to be polished under the following polishing conditions. In this evaluation, a silicon wafer (300 mm, blanket wafer) with a polysilicon (Poly-Si) film having a thickness of 5,000 Å formed on the surface, a silicon wafer (300 mm, blanket wafer) with a P-TEOS film (TEOS film (silicon dioxide film) formed by plasma CVD) having a thickness of 10,000 Å on the surface, and a silicon wafer (300 mm, blanket wafer) with a silicon nitride (SiN) film having a thickness of 3,000 Å formed on the surface were each used as the object to be polished.

### <<Polishing Conditions>>

Polishing device: CMP one-side polishing device for 200 mm Mirra, available from Applied Materials, Inc.
Polishing pad: hard polyurethane pad, IC1010, available from Nitta Haas Incorporated.
Polishing pressure: 2.0 psi
Number of revolutions of polishing table: 63 rpm
Number of revolutions of head (carrier): 57 rpm
Supply of polishing composition: free-flowing
Amount of polishing composition supplied: 100 mL/min
Polishing time: 60 seconds

The polishing removal rate was measured by determining the thickness using an optical film thickness meter (RE-3500, available from SCREEN Holdings Co., Ltd.) and dividing (thickness before polishing)-(thickness after polishing) by the polishing time. The ratio of the polishing removal rate of the polysilicon film (A/min) to the polishing removal rate of the P-TEOS film (Å/min) (polishing removal rate of the polysilicon film/polishing removal rate of the P-TEOS film) was calculated as the selection ratio. In addition, the ratio of the polishing removal rate of the polysilicon film (Å/min) to the polishing removal rate of the silicon nitride film (Å/min) (polishing removal rate of the polysilicon film/polishing removal rate of the silicon nitride film) was calculated as the selection ratio.

The polishing removal rate of the polysilicon (Poly-Si) film (Å/min), the polishing removal rate of the P-TEOS film (Å/min), and the polishing removal rate of the silicon nitride (SiN) film (Å/min) obtained from the above evaluation are shown in Table 3. In addition, the selection ratios (ratio between polishing removal rates) calculated from these polishing removal rates are shown in Table 3. In Table 3, the ratio of the polishing removal rate of polysilicon to the polishing removal rate of P-TEOS (polishing removal rate of polysilicon/polishing removal rate of P-TEOS) is described as Poly-Si/P-TEOS, and the ratio of the polishing removal rate of polysilicon to the polishing removal rate of silicon nitride (polishing removal rate of polysilicon/polishing removal rate of silicon nitride) is described as Poly-Si/SiN.

In Table 3, the evaluation items marked with “-” indicate that no evaluation was performed. Note that, the polishing composition of Comparative Example 3 was not evaluated for its polishing properties because aggregation occurred.

In this evaluation, a higher polishing removal rate of polysilicon is preferable.

In this evaluation, the ratio of the polishing removal rate of the polysilicon film to the polishing removal rate of the P-TEOS film is preferably 0.50 or more and 2.00 or less, more preferably 0.80 or more and 1.90 or less, still more preferably 0.90 or more and 1.90 or less, even still more preferably 1.00 or more and 1.80 or less, further more preferably 1.10 or more and 1.80 or less, further more preferably 1.10 or more and 1.70 or less, further more preferably 1.20 or more and 1.60 or less, further more preferably 1.20 or more and 1.50 or less, and particularly preferably 1.30 or more and 1.50 or less.

In this evaluation, the ratio of the polishing removal rate of the polysilicon film to the polishing removal rate of the silicon nitride film is not particularly limited. However, in this evaluation, the ratio of the polishing removal rate of the polysilicon film to the polishing removal rate of the silicon nitride film is preferably 2.50 or more and 10.00 or less, more preferably 2.50 or more and 9.00 or less, still more preferably 3.00 or more and 8.50 or less, even still more preferably 3.00 or more and 8.00 or less, further more preferably 4.00 or more and 7.50 or less, further more preferably 5.00 or more and 7.50 or less, further more preferably 6.00 or more and 7.00 or less, and particularly preferably 6.20 or more and 6.80 or less.

TABLE 2
Compositions and characteristics of polishing compositions

| | Composition | | | | | | | | | |
|---|---|---|---|---|---|---|---|---|---|---|
| | | | | | Compound containing | | | | | |
| | | | | | polyoxyalkylene | | | | | |
| | Silica particles | | Acid or base | | chain | | Salt compound | | Characteristics | |
| | | Content | | Content | | Content | | Content | | Electrical |
| Polishing | | [% by | | [% by | | [% by | | [% by | | conductivity |
| composition | Kind | mass] | Kind | mass] | Kind | mass] | Kind | mass] | pH | [mS/cm] |
| Comparative | Unmodified | 4 | Nitric | 0.045 | — | — | — | — | 2.2 | 2.78 |
| Example 1 | colloidal silica | | acid | | | | | | | |
| Comparative | Surface- | 4 | Nitric | 0.045 | — | — | — | — | 2.2 | 3.01 |
| Example 2 | modified | | acid | | | | | | | |
| | colloidal silica 2 | | | | | | | | | |
| Example 1 | Surface- | 4 | Nitric | 0.045 | — | — | — | — | 2.2 | 3.01 |
| | modified | | acid | | | | | | | |
| | colloidal silica 3 | | | | | | | | | |
| Example 2 | Surface- | 4 | Nitric | 0.045 | — | — | — | — | 2.2 | 3.01 |
| | modified | | acid | | | | | | | |
| | colloidal silica 4 | | | | | | | | | |
| Example 3 | Surface- | 4 | Nitric | 0.045 | — | — | — | — | 2.2 | 3.01 |
| | modified | | acid | | | | | | | |
| | colloidal silica 5 | | | | | | | | | |
| Example 4 | Surface- | 4 | Nitric | 0.045 | — | — | — | — | 2.2 | 3.01 |
| | modified | | acid | | | | | | | |
| | colloidal silica 1 | | | | | | | | | |
| Example 5 | Surface- | 4 | Nitric | 0.045 | Polyethylene | 0.001 | — | — | 2.2 | 2.94 |
| | modified | | acid | | glycol 1 | | | | | |
| | colloidal silica 1 | | | | | | | | | |
| Example 6 | Surface- | 4 | Nitric | 0.045 | — | — | — | — | 2.2 | 3.01 |
| | modified | | acid | | | | | | | |
| | colloidal silica 6 | | | | | | | | | |
| Example 7 | Surface- | 4 | Nitric | 0.045 | — | — | — | — | 2.2 | 3.01 |
| | modified | | acid | | | | | | | |
| | colloidal silica 7 | | | | | | | | | |
| Example 8 | Surface- | 4 | Nitric | 0.045 | — | — | — | — | 2.2 | 3.01 |
| | modified | | acid | | | | | | | |
| | colloidal silica 8 | | | | | | | | | |
| Comparative | Surface- | 4 | Nitric | 0.045 | — | — | — | — | 2.2 | 3.01 |
| Example 3 | modified | | acid | | | | | | | |
| | colloidal silica 9 | | | | | | | | | |
| Comparative | Unmodified | 4 | Nitric | 0.045 | Polyethylene | 0.001 | — | — | 2.2 | 2.89 |
| Example 4 | colloidal silica | | acid | | glycol 1 | | | | | |
| Comparative | Surface- | 4 | Potassium | 0.00002 | — | — | — | — | 8.1 | 0.92 |
| Example 5 | modified | | hydroxide | | | | | | | |
| | colloidal silica 1 | | | | | | | | | |
| Example 9 | Surface- | 4 | Nitric | 0.00004 | — | — | — | — | 5.2 | 1.15 |
| | modified | | acid | | | | | | | |
| | colloidal silica 1 | | | | | | | | | |
| Example 10 | Surface- | 4 | Nitric | 0.045 | — | — | Ammonium | 4.51 | 2.2 | 10.77 |
| | modified | | acid | | | | sulfate | | | |
| | colloidal silica 1 | | | | | | | | | |

TABLE 3
Evaluation results of polishing performances

| | Polishing removal rate | | | Selection ratio | |
|---|---|---|---|---|---|
| | Poly-Si | P-TEOS | SiN | Poly-Si/ | Poly- |
| Polishing composition | [Å/min] | [Å/min] | [Å/min] | P-TEOS | Si/SiN |
| Comparative Example 1 | 46 | 313 | 58 | 0.15 | 0.79 |
| Comparative Example 2 | 121 | 248 | 59 | 0.49 | 2.05 |
| Example 1 | 172 | 188 | 52 | 0.91 | 3.31 |
| Example 2 | 179 | 184 | 51 | 0.97 | 3.51 |
| Example 3 | 192 | 161 | 48 | 1.19 | 4.00 |
| Example 4 | 205 | 149 | 32 | 1.38 | 6.41 |
| Example 5 | 189 | 149 | 32 | 1.27 | 5.91 |
| Example 6 | 199 | 145 | 34 | 1.37 | 5.85 |
| Example 7 | 167 | 126 | 27 | 1.33 | 6.19 |
| Example 8 | 101 | 120 | 21 | 0.84 | 4.81 |
| Comparative Example 3 | — | — | — | — | — |
| Comparative Example 4 | 17 | 305 | 76 | 0.06 | 0.22 |
| Comparative Example 5 | 451 | 222 | 21 | 2.03 | 21.48 |
| Example 9 | 269 | 197 | 33 | 1.37 | 8.15 |
| Example 10 | 211 | 121 | 42 | 1.74 | 5.02 |

It is confirmed from the results of Comparative Example 1 and Examples 1 to 10, that the polishing composition containing: the surface-modified silica particles that contain the surface-modifying group containing a polyoxyalkylene chain having a specific weight average molecular weight; and water, can achieve a high polishing removal rate of a material having a silicon-silicon bond and satisfies a ratio of a polishing removal rate of the material having an oxygen-silicon bond to a polishing removal rate of the material having a silicon-silicon bond within a good range.

It is confirmed from the results of Example 4 and Comparative Example 4, that the effect of the present disclosure cannot be obtained when a polishing composition simply contains only the compound containing a polyoxyalkylene chain, and the effect of the present disclosure is obtained when a polishing composition contains the surface-modified silica particles that contain the surface-modifying group containing a polyoxyalkylene chain having a specific weight average molecular weight.

It is confirmed from the results of Examples 4 and 9 and Comparative Example 5, that the effect of the present disclosure is obtained when the polishing composition has a pH of less than 7, for example, when the pH is 2.2 as in Example 4, and when the pH is 5.2 as in Example 9, while the effects of the present disclosure is not obtained when the polishing composition has a high pH, for example, when the pH is 8.1 as in Comparative Example 5.

1. A polishing composition comprising the following component (A) and the following component (B) and having a pH of less than 7:
component (A): surface-modified silica particles containing silica particles and a surface-modifying group that modifies a surface of the silica particles and contains a polyoxyalkylene chain having a weight average molecular weight of 80 or more and 7,000 or less; and
component (B): water.

2. The polishing composition according to claim 1, wherein a weight average molecular weight of the polyoxyalkylene chain is 80 or more and 600 or less.

3. The polishing composition according to claim 1, wherein the component (A) contains silica particles containing a compound containing a polyoxyalkylene chain fixed on a surface of the particles through a silane coupling agent.

4. The polishing composition according to claim 3, wherein the compound containing a polyoxyalkylene chain is a compound composed of only a polyalkylene glycol chain.

5. The polishing composition according to claim 4, wherein the compound composed of only a polyalkylene glycol chain is at least one compound selected from the group consisting of polyethylene glycol, polypropylene glycol, and a polyethylene glycol-polypropylene glycol copolymer.

6. The polishing composition according to claim 3, wherein the silane coupling agent contains an isocyanate group-containing silane coupling agent.

7. The polishing composition according to claim 1, wherein the pH is 1 or more and less than 6.

8. The polishing composition according to claim 1, wherein the polishing composition has electrical conductivity of 0.5 mS/cm or more and 10 mS/cm or less.

9. The polishing composition according to claim 1, wherein the polishing composition has such a characteristic that a ratio of a polishing removal rate of a material having a silicon-silicon bond to a polishing removal rate of a material having an oxygen-silicon bond is 0.50 or more and 2.00 or less.

10. The polishing composition according to claim 1, which is used for polishing an object to be polished containing a material having an oxygen-silicon bond and a material having a silicon-silicon bond.

11. A polishing method, comprising polishing an object to be polished containing a material having an oxygen-silicon bond and a material having a silicon-silicon bond by using the polishing composition according to claim 1.

12. The polishing method according to claim 11, wherein a ratio of a polishing removal rate of the material having a silicon-silicon bond to a polishing removal rate of the material having an oxygen-silicon bond is 0.50 or more and 2.00 or less.
